(19) United States
(12) Patent Application Publication
(10) Pub. No.: US 2011/0029287 A1
(43) Pub. Date: Feb. 3, 2011

(54) Self-Diagnosing Transducers and Systems and Methods Therefor

(75) Inventors: Hoon Sohn, Daejeon (KR); Sang Jun Lee, Atlanta, GA (US)

Correspondence Address: DOWNS RACHLIN MARTIN PLLC, 199 MAIN STREET, P O BOX 190, BURLINGTON, VT, 05402-0190, US

(73) Assignee: CARNEGIE MELLON UNIVERSITY, Pittsburgh, PA (US)

(21) Appl. No.: 12/845,401

(22) Filed: Jul. 28, 2010

Related U.S. Application Data
(60) Provisional application No. 61/273,161, filed on Jul. 31, 2009.

(51) Int. Cl. G01R 27/26

(52) U.S. Cl. 702/189; 324/685

(57) ABSTRACT

A transducer system that includes a piezoelectric transducer and a self-diagnosis system electrically connected to the transducer. In one embodiment, the self-diagnosis system is configured to detect when a debonding defect has occurred in the bond between the transducer and a host structure and to detect when a crack has occurred in the transducer itself. The self-diagnosis system implements debonding-detection and crack-detection schemes that can distinguish between debonding and cracking, as well as distinguish these problems from changes arising from temperature variation.

### RELATED APPLICATION DATA

This application claims the benefit of priority of U.S. Provisional Patent Application Ser. No. 61/273,161, filed Jul. 31, 2009, and titled “Methods, Apparatuses, And Systems For Self-Diagnosis Of Piezoelectric Transducers,” which is incorporated by reference herein in its entirety.

### STATEMENT REGARDING FEDERALLY SPONSORED RESEARCH AND DEVELOPMENT

This invention was made with partial government support under National Science Foundation Grant No. CMS-0529208. The U.S. Government may have certain rights in this invention.

### FIELD OF THE INVENTION

The present invention generally relates to the field of transducers. In particular, the present invention is directed to self-diagnosing transducers and systems and methods therefor.

### BACKGROUND

There are increasing demands for structural health monitoring (SHM) and non-destructive testing (NDT) technologies for monitoring and maintaining aerospace, civil infrastructure, and mechanical systems. In particular, autonomous SHM systems using active sensing devices have been studied extensively to diagnose current structural states in near real-time and aim to eventually reduce the life-cycle costs of such systems and structures by replacing current schedule-based maintenance with condition-based maintenance. These SHM systems are also expected to reduce the present human labor, human errors, and downtime related to the schedule-based maintenance. Among several active sensing devices used for SHM applications, devices based on piezoelectric materials, such as wafer-type lead zirconate titanate (PZT), are commonly used because of their compactness, light weight, low power consumption, and low cost.

Conventional SHM studies using surface-mountable wafer-type piezoelectric transducers are mainly concerned with structural damage identification, but not so much with functionality of the transducers themselves. However, the transducers often can be the weakest links in the entire system because they also experience various external loadings and environmental variations and can develop problems caused by these loadings and environmental conditions.

When the piezoelectric transducers have been used in SHM applications, it has been assumed that these transducers are perfectly bonded to a structure and that their bonding conditions do not change throughout their service lives. It is also assumed that the transducers will not experience any internal fractures or cracks. However, these assumptions are not valid in real-life applications.

One of the possible defects piezoelectric transducers can develop during service is that they can become debonded from a host structure. This debonding issue is directly related to the performance of an SHM system, because the measured mechanical response from the host structure does not reflect the proper structural states, since the bad coupling between the transducer and the structure introduces error into the SHM system. Another possible defect that piezoelectric transducers can experience is cracking. A completely broken transducer can be easily identified because no meaningful output signals from the transducer will be measured. However, if there is only a small fracture or crack in the piezoelectric transducer, it still performs relatively sufficiently. In spite of the transducer still working, it is possible for the transducer to falsely indicate a structure's current state when using any baseline data obtained from the intact transducer.

### SUMMARY OF THE DISCLOSURE

In one implementation, the present disclosure is directed to a method that includes: monitoring a piezoelectric transducer for a change in capacitance of the piezoelectric transducer; and implementing, as a function of the monitoring, a baseline-free process to determine if a defect condition is present or if the change in capacitance is due to a change in temperature of the piezoelectric transducer.

In another implementation, the present disclosure is directed to a method that includes: repeatingly inputting an input signal into a piezoelectric transducer secured to a host structure; repeatingly generating a response signal representing the response of the piezoelectric transducer to the input signal; repeatingly time-reversing the response signal to obtain a time-reversed response signal; repeatingly inputting the time-reversed response signal into the piezoelectric transducer; repeatingly obtaining a reconstructed signal representing the response of the piezoelectric transducer to time-reversed response signal; repeatingly calculating time-reversal and symmetry indices as a function of the reconstructed signal and the input signal; monitoring the time-reversal and symmetry indices over time to determine when a change occurs in the time-reversal and symmetry indices; and in response to the change occurring, automatedly taking an action.

In still another implementation, the present disclosure is directed to a method that includes: repeatingly applying a driving signal to the piezoelectric transducer at a selected frequency; repeatingly generating an output signal representing the output of the piezoelectric transducer that corresponds to the driving signal; repeatingly determining a Lamb wave energy ratio index as a function of the driving signal and the output signal; monitoring the Lamb wave energy ratio index over time to determine when a change occurs in the Lamb wave energy ratio index; and in response to the change occurring, automatedly taking an action.

In still another implementation, the present disclosure is directed to a machine-readable medium containing machine-executable instructions for implementing a method of self-diagnosing a piezoelectric transducer. The machine-executable instructions include: a first set of machine-executable instructions for monitoring the piezoelectric transducer for a change in capacitance of the piezoelectric transducer; and a second set of machine-executable instructions for implementing, as a function of the monitoring, a baseline-free process to determine if a defect condition is present or if the change in capacitance is due to a change in temperature of the piezoelectric transducer.

In yet another implementation, the present disclosure is directed to a machine-readable medium containing machine-executable instructions for implementing a method of self-diagnosing a piezoelectric transducer. The machine-executable instructions include: machine-executable instructions for repeatingly inputting an input signal into a piezoelectric transducer secured to a host structure; machine-executable instructions for repeatingly generating a response signal representing the response of the piezoelectric transducer to the input signal; machine-executable instructions for repeatingly time-reversing the response signal to obtain a time-reversed response signal; machine-executable instructions for repeatingly inputting the time-reversed response signal into the piezoelectric transducer; machine-executable instructions for repeatingly obtaining a reconstructed signal representing the response of the piezoelectric transducer to time-reversed response signal; machine-executable instructions for repeatingly calculating time-reversal and symmetry indices as a function of the reconstructed signal and the input signal; machine-executable instructions for monitoring the time-reversal and symmetry indices over time to determine when a change occurs in the time-reversal and symmetry indices; and machine-executable instructions for automatedly taking an action in response to the change occurring.

In still yet another implementation, the present disclosure is directed to a machine-readable medium containing machine-executable instructions for implementing a method of self-diagnosing a piezoelectric transducer. The machine-executable instructions include: machine-executable instructions for repeatingly applying a driving signal to the piezoelectric transducer at a selected frequency; machine-executable instructions for repeatingly generating an output signal representing the output of the piezoelectric transducer that corresponds to the driving signal; machine-executable instructions for repeatingly determining a Lamb wave energy ratio index as a function of the driving signal and the output signal; machine-executable instructions for monitoring the Lamb wave energy ratio index over time to determine when a change occurs in the Lamb wave energy ratio index; and machine-executable instructions for automatedly taking an action in response to the change occurring.

In a further implementation, the present disclosure is directed to a transducer system that includes: a piezoelectric transducer having a capacitance; and a self-diagnosis system configured for: monitoring the piezoelectric transducer for a change in the capacitance of the piezoelectric transducer; and implementing, as a function of the monitoring, a baseline-free process to determine if a defect condition is present or if the change in capacitance is due to a change in temperature of the piezoelectric transducer.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a schematic diagram of a self-diagnosing piezoelectric transducer system, shown engaged with a host structure;

FIG. 2 is a diagram illustrating a self-diagnosing method that can be implemented in a piezoelectric-material-based transducer;

FIG. 3 is a schematic diagram of a self-diagnosing piezoelectric transducer, illustrating a time-reversal method for detecting debonding of the piezoelectric material of the transducer from a substrate;

FIG. 4 is a schematic diagram of a piezoelectric material attached to a host structure, illustrating debonding of the piezoelectric layer from the host structure;

FIG. 5 is a schematic diagram of a piezoelectric transducer system used for numerical simulations and testing;

FIGS. 6A-C are diagrams of models that utilize the transducer system of FIG. 5 and that model, respectively, the piezoelectric material as intact and fully bonded, the piezoelectric material as intact and partially debonded, and the piezoelectric material as cracked and fully bonded;

FIGS. 7A-D are graphs illustrating, respectively, a 120 kHz toneburst input signal, an extracted mechanical-response signal, a time-reversed input signal, and a comparison of the input signal and a signal reconstructed from the time-reversed input signal, all from numerical simulations that utilized the transducer system of FIG. 5 and the models of FIGS. 6A-C;

FIGS. 8A-C are graphs showing comparisons between the original input waveforms and the reconstructed signals of the time-reversal process from numerical simulations that utilized, respectively, the three conditions of the models of FIGS. 6A-C;

FIG. 9 is a graph showing the group velocity of the 3 mm-thick aluminum plate of the transducer system of FIG. 5;

FIGS. 10A-D are graphs illustrating, respectively, measured output voltages in the time domain for a 150 kHz toneburst input signal, a zoomed-in version of the output voltages, a convergence of the Lamb-wave energy ratio (LWER) index with respect to measurement time durations, and the LWER index for three different piezoelectric material layer lengths under three temperature conditions, all from numerical simulations that utilized the transducer system of FIG. 5 and the models of FIGS. 6A-C;

FIG. 11 is a diagram of an experimental set-up used to perform tests on the piezoelectric transducer system of FIG. 5;

FIGS. 12A-C are enlarged partial plan views of the specimen setups for testing, respectively, an intact transducer, a transducer having a debonding defect, and a transducer having a cracking defect;

FIGS. 13A-D are graphs illustrating, respectively, a 120 kHz toneburst input signal, an extracted mechanical-response signal, a time-reversed input signal, and a comparison of the input signal and a signal reconstructed from the time-reversed input signal, all from tests that utilized the experimental setup of FIG. 11 and the specimen setups of FIGS. 12A-C;

FIGS. 14A-C are graphs showing comparisons between the original input waveforms and the reconstructed signals of the time-reversal process from testing that utilized, respectively, the experimental setup of FIG. 11 and the specimen setups of FIGS. 12A-C;

FIGS. 15A-D are graphs illustrating, respectively, measured output voltages in the time domain for a 150 kHz toneburst input signal, a zoomed-in version of the output voltages, a convergence of the Lamb-wave energy ratio (LWER) index with respect to measurement time durations, and the LWER index for three different piezoelectric material layer lengths under three temperature conditions, all from tests that utilized the experimental setup of FIG. 11 and the specimen setups of FIGS. 12A-C;

FIG. 16 is a diagram illustrating a continuous wavelet transform filtering process;

FIG. 17 is a table comparing the equations of motion in a transducer between the bonded region and the debonded region;

FIG. 18 is a table of numerical simulation parameters used in the time reversal process;

FIG. 19 is a table of quantitative numerical simulation results of the estimated scaling factors under different transducer conditions;

FIG. 20 is a table of quantitative numerical simulation results of the time-reversal/symmetry indices with a 120 kHz toneburst input signal;

FIG. 21 is a table of quantitative experimental results of the estimated scaling factors under different transducer conditions; and

FIG. 22 is a table of quantitative experimental results of the time-reversal/symmetry indices with a 120 kHz toneburst input signal.

### DETAILED DESCRIPTION

The present disclosure describes piezoelectric-material-based devices that self-diagnose the state of their bond to a host structure and/or whether the piezoelectric material is cracked. This disclosure also describes methods and systems for performing baseline-free self-diagnosis in such devices. These systems and methods implement reliable and simple piezoelectric transducer self-sensing schemes and a smart piezoelectric transducer self-diagnosis scheme that is robust to environmental variations and structural damages.

The self-sensing schemes disclosed herein take full advantage of the fact that piezoelectric transducers have particular responses to signals applied to them. Advantages of schemes of the present disclosure are their simplicity and adaptability. The hardware that needs to be added to a transducer to implement schemes of the present invention includes a simple self-sensing circuit, which can be equivalent to a voltage divider. These schemes minimize the chances of transducer malfunctions from operational and environmental variations and can be used to generate an alert when a defect is detected in a transducer so that, for example, the transducer can be replaced or data collected by that transducer can be ignored. Another advantage of a self-sensing scheme of the present disclosure is that the self-sensing parameters can be calibrated instantaneously in the changing operational and environmental conditions of the system.

The greatest challenge of self-diagnosis comes from the fact that the diagnosis method should be robust to other factors, such as environmental variations and structural damages, when monitoring the current state of the piezoelectric transducer. Conventionally, the capacitance value of a piezoelectric transducer is monitored to identify an abnormal condition because the capacitance value is related to the size of the transducer and the condition of the bond between the transducer and a host structure. However, the capacitance value is also influenced by ambient temperature. Therefore, conventional self-diagnosis schemes can generate false alarms on the current state of the transducer. To minimize this possibility, the present disclosure describes two different schemes: 1) a debonding-detection scheme for detecting debonding (or incomplete bonding) between a transducer and a host structure and that does not rely on the previously obtained baseline data, which is likely to be affected by environmental variations and structural damages, using time reversal acoustics (TRA); and 2) a cracking-detection scheme for detecting cracking of a transducer that is robust to environmental variations and structural damages by monitoring Lamb wave propagation energy. As described below, these schemes can be implemented separately or together in an overall baseline-free self-diagnosing method, which can be implemented in a transducer as desired.

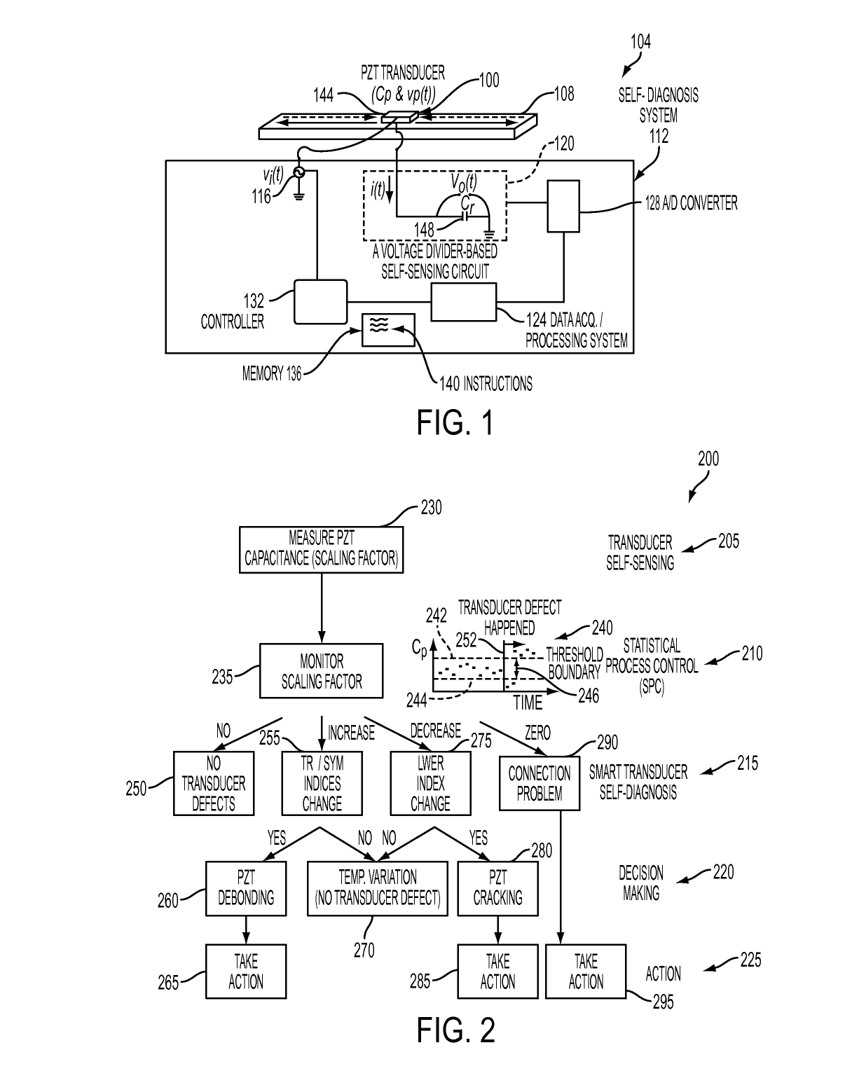

An important characteristic of a piezoelectric material, such as lead zirconate titanate (PZT), among others, is that it can be used for simultaneous sensing and actuation. This characteristic enables a piezoelectric transducer, such as transducer 100 of transducer system 104 in FIG. 1, to monitor its current state by itself (this is referred to as “transducer self-diagnosis”), thus minimizing the false alarms due to the current state of a host structure 108 to which the transducer is attached. For this purpose, piezoelectric transducer system 104 implements a self-sensing scheme, which in one embodiment of the present invention requires a self-diagnosis system 112 configured/programmed to perform the debonding-detection and cracking-detection schemes noted above.

In this example, self-diagnosis system 112 includes a waveform generator 116, for providing various stimulating signals to transducer 100, and a self-sensing circuit 120, for sensing the transducer's responses to those signals. Self-diagnosis system 112 also includes a data acquisition/processing system 124 that acquires measurement data from self-sensing circuit 120 and processes that data in a manner that provides sensor system 104 with the functionality described herein. An analog-to-digital converter 128 converts the analog signal at self-sensing circuit 120 to the digital format required by data acquisition/processing system 124. A controller 132 controls the overall operation of self-diagnosis system 112, including controlling waveform generator 116 and controlling data acquisition/processing system 124. It is noted that self-diagnosis system 112 can include any suitable combination of hardware and/or software, such as dedicated hardwired-logic circuitry, or an application-specific integrated circuit, system-on-chip, or general processor in combination with one or more software instruction sets for carrying out the schemes and methods disclosed herein. Those skilled in the art will understand how to implement self-diagnosis system 112, for example, by choosing the necessary components and/or by programming the various components, after reading this entire disclosure, such that further details on these components are not necessary for those skilled in the art to implement the present invention to its broadest scope.

When self-diagnosis system 112 is an instruction-based system, self-diagnosis system 112 includes one or more memories 136, or other machine-readable medium, containing machine-executable instructions 140 for providing the self-diagnosis system with the necessary functionality. Generally, a machine-readable medium includes any apparatus or device capable of storing machine-executable instructions 140 and that allow for access of those instructions for execution within self-diagnosis system 112.

In this embodiment of transducer system 104, the focus is on implementing a simple and reliable self-sensing scheme that is easy to apply to piezoelectric-transducer-based structural health monitoring (SHM) systems with minimal additional hardware and cost. Based on this self-sensing scheme, the present inventors developed a transducer self-diagnosing scheme. An important feature of this self-diagnosing scheme is its robustness to structural damages and environmental variations, such as temperature variation. Without this feature, it is highly possible that a false alarm of the current condition of transducer 100 occurs in a similar manner to the false identification of structural damages.

Referring now to FIG. 2, and also to FIG. 1, FIG. 2 illustrates an exemplary baseline-free self-diagnosing (BFSD) method 200 in accordance with the present invention that is carried out by self-diagnosis system 112 of transducer system 104 of FIG. 1. In this example, BFSD method 200 includes five general categories of procedures: 1) a transducer self-sensing category 205; 2) a statistical process control (SPC) category 210; 3) a smart-transducer self-diagnosing category 215; 4) a decision making category 220; and 5) an action category 225. For convenience, BFSD method 200 is described relative to transducer system 104 of FIG. 1, though those skilled in the art should readily appreciate that BFSD method 200 and other methods and schemes disclosed herein can be used with other transducer systems.

At step 230, a parameter of transducer 100 that varies in a known relationship with the capacitance of the piezoelectric material of the transducer, such as a scaling factor that is defined by self-sensing circuit 120, is measured. By estimating the capacitance from this parameter, the change of the capacitance value in transducer 100 can be monitored, here at step 235. Step 235 effectively includes determining whether or not a current capacitance value is above or below certain corresponding thresholds. This is illustrated by graph 240 of FIG. 2, which is a plot of capacitance versus time for an exemplary scenario. Graph 240 shows an upper threshold 242 and a lower threshold 244 that define an acceptable-value window 246. When a current capacitance of transducer 100 falls within acceptable-value window 246, the transducer is assumed at step 250 to be operating correctly and no further diagnosis is performed. Rather, BFSD method 200 can simply continue to continually measure and monitor the parameter (see steps 230, 235).

However, if it is determined at step 235 that the current capacitance value of transducer 100 is above upper threshold 242 via the measured parameter (which occurs in graph 240 at a time after the time represented by line 252), the transducer may be experiencing debonding from host structure 108 or a temperature increase due to ambient conditions. To determine which condition is present, at step 255 BFSD method 200 performs a process to determine whether the increase in the capacitance value is due to debonding or a temperature increase. In one example, step 255 may include examining time reversal (TR) and symmetry (SYM) indices to determine whether they have changed from one or more previous iterations of step 255. These TR and SYM indices and corresponding methods are described below in detail. If at step 255 it is determined that the TR and SYM indices have changed, it is determined at step 260 that debonding has occurred, and BFSD method 200 proceeds to step 265 at which an action is taken that relates to the debonding problem. For example, self-diagnosis system 112 may issues an alert and/or may nullify the data collected by the debonded transducer or otherwise flag the data as being tainted. However, if it is determined at step 255 that the TR and SYM indices have not changed, then at step 270 it is determined that the changes were due to temperature variation and not debonding, and BFSD method 200 continues to continually measure and monitor the parameter (see steps 230, 235).

Conversely, if it is determined at step 235 that the current capacitance value of transducer 100 is below lower threshold 244 via the measured parameter (which occurs in graph 240 at a time after the time represented by line 252), the transducer may be cracked or experiencing a temperature decrease due to ambient conditions. To determine which condition is present, at step 275 BFSD method 200 performs a process to determine whether the decrease in the capacitance value is due to cracking or a decrease in temperature. In one example, step 275 may include examining a Lamb wave energy ratio (LWER) index to determine whether it has changed from one or more previous iterations of step 275. The LWER index and corresponding methods are described below in detail. If at step 275 it is determined that the LWER index has changed, it is determined at step 280 that cracking has occurred, and BFSD method 200 proceeds to step 285 at which an action is taken relating to transducer 100 having a cracking problem. For example, self-diagnosis system 112 may issues an alert and/or may nullify the data collected by the debonded transducer or otherwise flag the data as being tainted. However, if it is determined at step 275 that the LWER index has not changed, then at step 270 it is determined that the change was due to temperature variation and not cracking, and BFSD method 200 continues to continually measure and monitor the parameter (see steps 230, 235).

If it is determined at step 235 that the current capacitance value of transducer 100 as determined via the measured parameter is zero, then at step 290 it is determined that a connection problem exists, and BFSD method 200 proceeds to step 295 at which self-diagnosis system 112 takes an action, such as issuing an alert that transducer 100 has a connection problem.

With exemplary BFSD method 200 having been presented in the context of transducer system 104, the following section describes the transducer self-sensing schemes in greater detail and presents a theoretical derivation of features of the schemes with three different identification features of transducer defects.

### Transducer Self-Sensing

This section describes the theoretical framework of a self-sensing scheme according to the present invention. In particular, this section describes: 1) an exemplary embodiment of self-sensing circuit 120 in detail; 2) the relationship between input and output voltages utilized by BFSD method 200; 3) a scaling-factor example of the measured parameter; and 4) an orthogonal method to estimate the scaling factor.

Referring again to FIG. 1, a free surface 144 of piezoelectric transducer 100 is connected to signal generator 116 that provides an input voltage (νᵢ), and the other surface, which is bonded to host structure 108, is tied to self-sensing circuit 120 equivalent to a voltage divider. Then, an output voltage (νₒ) from self-sensing circuit 120 is provided to data acquisition/processing system 124, which uses the known input signal (νᵢ) and the measured output voltage (νₒ) to calculate a proposed scaling factor, using, in this example, an orthogonality method. The measured output voltage (νₒ) is then utilized for the self-diagnosis scheme.

The output voltage (νₒ) of self-sensing circuit 120 is related to the input voltage (νᵢ) and the mechanical voltages of piezoelectric transducer 100 as follows:

i(t)=Cₚ[\dot{ν}ᵢ(t)+\dot{ν}ₚ(t)−\dot{ν}ₒ(t)]=Cᵣ\dot{ν}ₒ(t) Eq. (1)

Cₚ∫₀^{t}(\dot{ν}ᵢ(t)+\dot{ν}ₚ(t)−\dot{ν}ₒ(t))dτ=Cᵣ∫₀^{t}\dot{ν}ₒ(t)dτ Eq. (2)

wherein:
Cₚ and Cᵣ are the capacitance of the transducer and the capacitance of a reference capacitor 148 of the self-sensing circuit, respectively; and
νₚ(t) is the mechanical response of host structure 108.
   It is shown that the output from self-sensing circuit 120 is related to the input and mechanical response of transducer 100 as well as the capacitance values of the transducer and reference capacitor 148. When a sinusoidal input, νᵢ(t)=V sin(ωt), is applied to transducer 100 and the driving frequency ω is high enough, the term νₚ(t) in Equation (2) is negligible. Then, the steady-state solution of Equation (2) becomes:

$${v}_{0} ( t ) = \frac{{C}_{p}}{{C}_{p} + {C}_{r}} ( {v}_{i} ( t ) + {v}_{p} ( t ) ) ≅ \frac{{C}_{p}}{{C}_{p} + {C}_{r}} {v}_{i} ( t ) \qquad Eq . ( 3 )$$

Here, the scaling factor of the proposed self-sensing circuit is defined as the ratio of Cₚ to (Cₚ+Cᵣ),

$$SF = \frac{{C}_{p}}{{C}_{p} + {C}_{r}} ≅ \frac{{v}_{o} ( t )}{{v}_{i} ( t )} \qquad Eq . ( 4 )$$

Equation (4) indicates that the scaling factor can be approximated by computing the amplitude ratio of output voltage (νₒ) to input voltage (νᵢ) when the driving frequency is high enough.

To estimate the scaling factor from the input and output voltages using the orthogonality method, the numerator and denominator in Equation (4) are first multiplied by a sinusoidal wave having the frequency of input voltage (νᵢ). Then, the numerator and denominator are summed over the entire length of the signal:

$${SF}_{ORT} = {\sum }_{k = 0}^{m} {\tilde{v}}_{o} [ k ] \cdot sin ( ω k Δ t ) / {\sum }_{k = 0}^{m} {\tilde{v}}_{i} [ k ] \cdot sin ( ω k Δ t ) \qquad Eq . ( 5 )$$

wherein:
\tilde{ν}ₒ[k] and \tilde{ν}ᵢ[k] denote noise-contaminated versions of the input and output voltages and are defined as \tilde{ν}₀[k]=νₒ[k]+eₒ[k] and \tilde{ν}ᵢ[k]=νᵢ[k]+eᵢ[k], respectively;
eₒ[k] and eᵢ[k] are output and input Gaussian white noises;
νₒ[k] is a discrete version of the continuous signal νₒ(t) and is defined as ν₀[k]=νₒ(k×Δt)
Δt is the time sampling interval; and
νᵢ[k] is defined in a fashion similar to νₒ[k].
   Since the orthogonality algorithm uses an ideal sinusoidal signal that does not have a noise term, the orthogonality method is expected to be less susceptible to input and output noises. This scaling factor can be used in step 235 of BFSD method 200 of FIG. 2 to monitor the change in the condition of transducer 100. The scaling factor can be properly estimated by employing a high frequency sinusoidal excitation.

### Scaling Factor for Piezoelectric Capacitance Change Detection

This subsection describes a first transducer self-diagnosis scheme that BFSD method 200 can implement based on change in the scaling factor. Here, the effects of cracking and debonding of transducer 100 on the capacitance value of the transducer are analyzed. To show these effects on the capacitance value, this section addresses the following three main topics: 1) the admittance of transducer 100; 2) the effect of transducer debonding on the capacitance value; and 3) the effect of transducer cracking on the capacitance value.

The admittance of a piezoelectric transducer, such as transducer 100, attached to a structure, such as host structure 108, is described as:

$$Y ( ω ) = iω \frac{A}{{h}_{a}} ( \begin{matrix}{ɛ}_{33}^{T} - {d}_{31}^{2} {Y}_{a} + \\ \frac{{Z}_{a} ( ω )}{{Z}_{a} ( ω ) + {Z}_{b} ( ω )} {d}_{31}^{2} {Y}_{a} ( \frac{tan ξ {l}_{a}}{ξ {l}_{a}} )\end{matrix} ) \qquad Eq . ( 6 )$$

wherein:
A, hₐ, lₐ and Yₐ are the surface area, the thickness, the length and the Young's modulus of the transducer, respectively;
d₃₁ is the xz-directional induced strain coefficient;
∈₃₃^{T} is the z-directional dielectric permittivity;
Zₐ(ω) is the mechanical impedance of the transducer;
Z_{b}(ω) is the mechanical impedance of the structure; and
ξ is the wavenumber, respectively.
   If the PZT wafer is assumed to be a pure capacitor, the PZT capacitance value becomes:

$${C}_{p} ( ω ) = \frac{A}{{h}_{a}} ( {ɛ}_{33}^{T} - Re \{ \frac{{Z}_{b} ( ω )}{{Z}_{a} ( ω ) + {Z}_{b} ( ω )} \} \cdot {d}_{31}^{2} {Y}_{a} ) \qquad Eq . ( 7 )$$

wherein:
tan(ξlₐ)/ξlₐ is assumed to be close to 1 in the frequency range used in the present application; and
Re{ } denotes the real part of a complex number.

Based on Equation (7), if debonding is present in transducer 100, its capacitance value becomes:

$${{C}_{p} ( ω ) \vert}_{debonding} = \frac{{A}_{1}}{{h}_{a}} {ɛ}_{33}^{T} + \frac{{A}_{2}}{{h}_{a}} ( {ɛ}_{33}^{T} - Re \{ \frac{{Z}_{b} ( ω )}{{Z}_{a} ( ω ) + {Z}_{b} ( ω )} \} \cdot {d}_{31}^{2} {Y}_{a} ) \qquad Eq . ( 8 )$$

wherein:
A₁ and A₂ are the debonded surface area and the bonded area of the transducer, respectively; and A₁+A₂=A.
   Equation (8) shows that the capacitance value of transducer 100 and the corresponding scaling factor increases as the debonding progresses.

Based on Equation (7), when there is cracking in transducer 100, its capacitance value becomes:

$${{C}_{p} ( ω ) \vert}_{cracking} = \frac{{A}_{3}}{{h}_{a}} ( {ɛ}_{33}^{T} - Re \{ \frac{{Z}_{b} ( ω )}{{Z}_{a} ( ω ) + {Z}_{b} ( ω )} \} \cdot {d}_{31}^{2} {Y}_{a} ) \qquad Eq . ( 9 )$$

wherein A₃ is the remaining effective surface area of the transducer after cracking, which is always smaller than A. Equation (9) shows that the capacitance value of transducer 100 and the corresponding scaling factor decreases as the cracking progresses.

By monitoring the proposed scaling factor change at step 235 of BFSD method 200 of FIG. 2, abnormal behavior of transducer 100 can be detected. Similar to the electromagnetic (E/M) impedance method, this scaling factor feature has inevitable limitations, such as 1) it needs baseline data, and 2) temperature variation can affect the decision making because of the change of the piezoelectric material's properties. To overcome these limitations, additional self-diagnosis features, which are implemented in steps 255 and 275 of BFSD method 200 of FIG. 2, are described in the following subsections.

### TR/SYM Indices for Piezoelectric Debonding Detection

This subsection describes a scheme that a self-diagnosing method, such as BFSD method 200 of FIG. 2 (at step 255), can implement to determine whether debonding of a piezoelectric transducer has occurred. This scheme is based on TRA, which is used to extract a new analysis feature that is sensitive only to debonding. TRA can be used to reconstruct an input signal, such as the input voltage (νᵢ) of FIG. 1, at an excitation point if an output signal, such as the output voltage (νₒ) of FIG. 1, measured at the sensing point is reversed in the time domain and emitted back to the original excitation point. In the context of the present disclosure, the concept of the time reversal process (TRP) is extended so that the TRP can be still accomplished using a single piezoelectric transducer wherein the exciting and sensing points are identical.

The time reversibility and the symmetry of the original input waveform are not affected by the shape of the piezoelectric transducer. In other words, cracking of the transducer does not break the time reversibility and the symmetry. This subsection describes an exemplary transducer diagnosis scheme for detecting debonding of the transducer that is based on the TRA and guided wave propagations. Then, this section sets forth a possible reason why debonding can be detected by this transducer diagnosis scheme and analyzes the scheme theoretically. This section also describes TR and SYM indices that do not depend on the previously obtained data to differentiate debonding from the intact and cracking conditions, as well as from temperature variation.

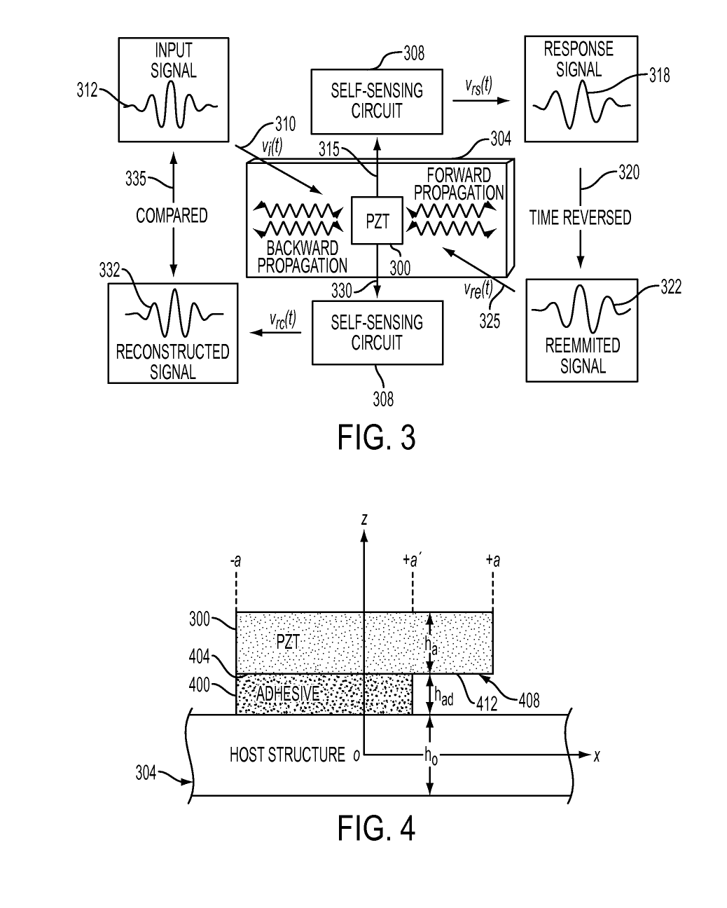

Referring now to FIG. 3, this figure illustrates a TRP-based scheme for diagnosing a piezoelectric transducer 300 engaged with a host structure 304 to determine whether debonding is present between the transducer and the host structure. The TRP utilizes a self-sensing circuit 308 and includes five procedures: 1) applying at step 310 a symmetric narrowband toneburst input signal (Vᵢ(t)) (represented by waveform 312) to transducer; 2) using the sensing circuit, measuring at step 315 the corresponding mechanical response of the transducer at an excitation point to obtain a response signal (Vᵣₛ(t)) (represented by waveform 318); 3) reversing at step 320 the response signal, scaled in the time domain, to obtain a reversed response signal (Vᵣₑ(t)) (represented by waveform 322) and then emitting at step 325 the reversed response signal into the transducer; 4) using the sensing circuit, sensing at step 330 the response of the transducer to the reversed response signal to obtain a reconstructed signal (V_{rc}(t)) (represented by waveform 332); and 5) comparing at step 335 the reconstructed signal to the original input signal. Due to the existence of multiple wave modes, wave propagation paths and reflections, the actual reconstructed signal (V_{rc}(t)) has several “sidebands,” i.e., a symmetric mode converted from an antisymmetric mode or vice versa. However, the shape of the “main mode” of the reconstructed signal (V_{rc}(t)), wherein most of the energy converges, remains identical to the original input signal (Vᵢ(t)), although the amplitude of the reconstructed signal is smaller than that of the original input signal due to attenuation. The reconstructed signal (V_{rc}(t)) is scaled so that the shape of the main mode in the reconstructed signal can be compared better with the shape of the input signal (Vᵢ(t)).

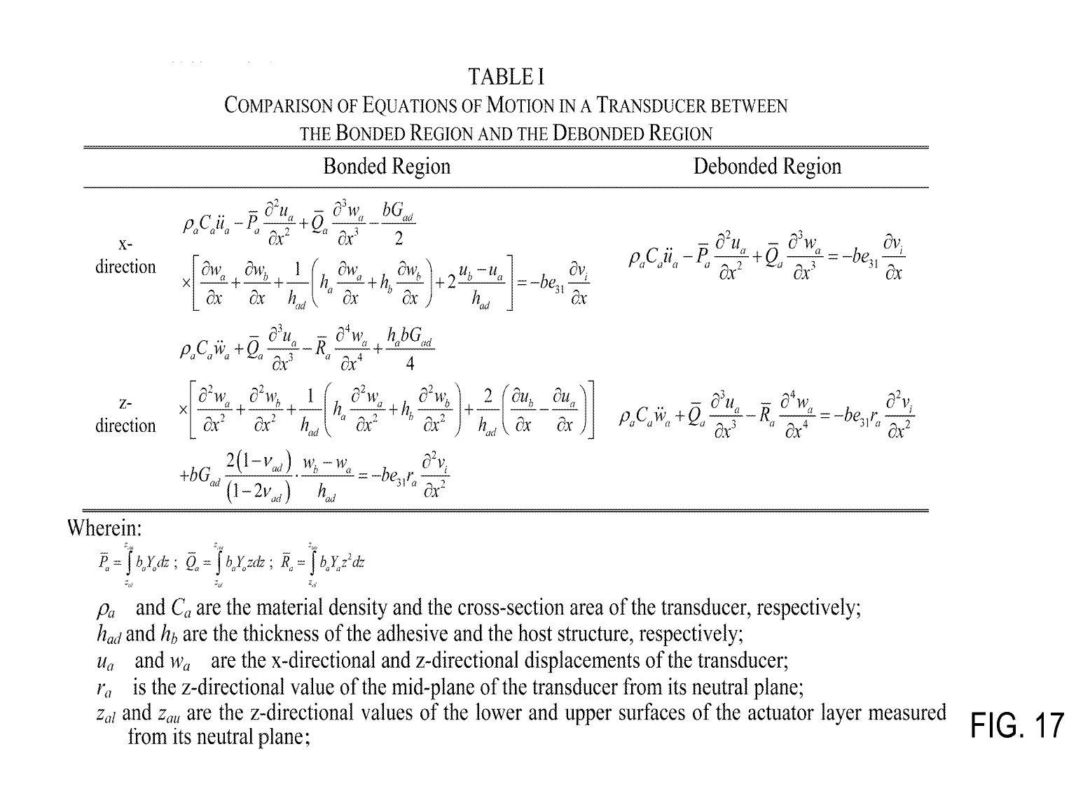

The identification of a debonding problem using the TRP is based on the premise that if there were debonding between piezoelectric transducer 300 and host structure 304, the time reversibility and symmetry of the input waveform 312 break down. More precisely, the shape of the main mode of the reconstructed signal (V_{rc}(t)) distorts from the shape of the original input signal (Vᵢ(t)). It is believed that this distortion exists because of a discrepancy between the total bondable area of transducer 300 and the actual bonded area of the transducer as illustrated in FIG. 4. As seen in FIG. 4, transducer 300 is bonded to host structure 304 by adhesive 400 over a bonded portion 404 of the bondable surface 408 of the transducer that is less than the entire bondable surface, leaving a second portion 412 unbonded. (Here, the “bondable” surface 408 in this example is the surface of transducer 300 facing host structure 304.) Since unbonded portion 412 is not coupled with host structure 304, the free vibration of the corresponding unbonded portion of transducer 300 induced by the input signal (Vᵢ(t)) and the reflections are not related to the TRP and consequently disturb the motion of the bonded portion 404. This implies that the main mode of the reconstructed signal (V_{rc}(t)) is attenuated and the corresponding sidebands of the reconstructed signal increase compared with the intact or cracked conditions of transducer 300. By examining the deviation of the main mode of the reconstructed signal (V_{rc}(t)) from the known input signal as shown in FIG. 3, the debonding problem is identified without requiring any prior baseline signals. Based on the theoretical foundation by others, the equations of motion in x and z directions at both bonded portion 404 (FIG. 4) and debonded portion 412 are derived as shown in Table I of FIG. 17. The vibration of the transducer at debonded region 412 is not coupled with the vibration of host structure 304.

To verify the previously discussed reason concerning the breakdown of the TRP with the debonding, the TRP is derived theoretically. When the input signal (Vᵢ(t)) is applied to transducer 300 in step 310, the corresponding response signal (Vᵣₛ(t)) can be represented as:

Vᵣₛ(ω)=kₛ(ω)G(ω)kₐ(ω)Vᵢ(ω) Eq. (10)

wherein:
kₛ(ω) and kₐ(ω) are the mechanical-electro efficient coefficient and the electro-mechanical efficient coefficient of the PZT wafer, respectively; and
G(ω) is the system's transfer function relating an input strain to an output strain at the PZT wafer.
   Note that the angular frequency, ω, is omitted from the following equations for simplicity unless stated otherwise. In a similar manner, the reconstructed signal (V_{rc}(t)) can be represented as:

$$\begin{matrix}{V}_{rc} = {k}_{s} {Gk}_{a} {V}_{re} \\ = {k}_{s} {Gk}_{a} {V}_{rs}^{*} \\ = {k}_{s} {k}_{s}^{*} {GG}^{*} {k}_{a} {k}_{a}^{*} {V}_{i}^{*}\end{matrix} \qquad Eq . ( 11 )$$

wherein Vᵣₑ is the reemitted reversed response signal (Vᵣₑ(t)) (FIG. 3).

In the case of the debonded portion of transducer 300, the system's transfer function can be described as:

G=G₁+G₂ Eq. (12)

wherein:
G₁ is the transfer function coupled with the response of host structure 304; and
G₂ is the transfer function related to the free vibration of the debonded portion of the transducer.
   Then, the reconstructed signal (V_{rc}(t)) of the debonded PZT wafer can be represented as:

V_{rc}=kₛkₛ*kₐkₐ*(G₁G₁*+G₂G₂*+G₁G₂*+G₂G₁*)Vᵢ* Eq. (13)

The first two terms of Equation (13) shows that the reconstructed signal (V_{rc}(t)) is a “time reversed” and “scaled” version of the original input signal (Vᵢ(t)). On the other hand, the last two terms of Equation (13) show that the time reversal is disturbed by the free vibration of the debonded portion of transducer 300.

To quantify the change of the main mode of the reconstructed signal (V_{rc}(t)) compared with the main mode of the original input signal (Vᵢ(t)), the TR and SYM indices are used. The TR index is described as:

$$TR = 1 - \sqrt{\frac{{\{ {\sum }_{k = {M}_{L}}^{{M}_{R}} I [ k ] \cdot V [ k ] \}}^{2}}{\{ {\sum }_{k = {M}_{L}}^{{M}_{R}} {( I [ k ] )}^{2} \cdot {\sum }_{k = {M}_{L}}^{{M}_{R}} {( V [ k ] )}^{2} \}}} \qquad Eq . ( 14 )$$

wherein I[k] and V[k] denote the discrete version of the known input signal (Vᵢ(t)) and the reconstructed signal (V_{rc}(t)), respectively. The time interval from the first peak of the main mode region to the seventh peak of the main mode region is used to calculate the TR and SYM indices. M_{L} and M_{R} represent the starting and ending data points of this time interval, respectively. If the shape of the main mode of the reconstructed signal (V_{rc}(t)) is identical to the shape of the main mode of the original input signal (Vᵢ(t)), the TR index becomes zero.

The SYM index is described as:

$$SYM = 1 - \sqrt{\frac{{\{ {\sum }_{k = {M}_{L}}^{{M}_{0}} L [ k ] \cdot R [ 2 {M}_{0} - k ] \}}^{2}}{\{ {\sum }_{k = {M}_{L}}^{{M}_{0}} {( L [ k ] )}^{2} \cdot {\sum }_{k = {M}_{0}}^{{M}_{R}} {( R [ k ] )}^{2} \}}} \qquad Eq . ( 15 )$$

wherein:
L[k] and R[k] denote the discrete version of the left-hand and right-hand sides of the main mode of the reconstructed signal (V_{rc}(t)) with respect to the center of the main mode;
M₀ is the center data point of the main mode; and
M_{L} and M_{R} represent the starting and ending data points as defined for the TR index.
   Similar to the TR index, if the shape of the main mode of the reconstructed signal (V_{rc}(t)) is perfectly symmetric, the SYM index becomes zero.

By monitoring the TR and SYM indices in a BFSD method of the present invention, such as at step 255 of BFSD method 200 of FIG. 2, debonding can be detected. The main advantage of these TRP-based indices is that they do not need any previously obtained baseline data. Also, the cracking of the piezoelectric transducer does not affect these indices. In addition, temperature variation affects the arrival time of guided waves, but does not affect the TRP and the corresponding TR and SYM indices.

### LWER Index for PZT Cracking Detection

This subsection describes a scheme that a self-diagnosing method of the present disclosure, such as BFSD method 200 of FIG. 2 (at step 275), can implement to determine whether cracking of a piezoelectric transducer has occurred. The only difference between an intact piezoelectric transducer and a cracked transducer is the actual size under the assumption that their bonding conditions are identical. To identify this size difference, a Lamb wave energy ratio (LWER) index is described herein based on a theoretical foundation for selective Lamb wave mode excitation. The LWER index is described as:

$$\begin{matrix}LWER ( ω , a ) = \frac{{E}_{{v}_{o}} ( ω , a )}{{E}_{{v}_{i}} ( ω , a )} \\ = \frac{{SF}^{2} \cdot ( {\sum }_{i = 1}^{{N}_{Ao}} {E}_{{v}_{{p}_{{A}_{0}}}}^{i} ( ω , a ) + {\sum }_{j = 1}^{{N}_{So}} {E}_{{v}_{{p}_{{S}_{0}}}}^{j} ( ω , a ) )}{{( SF \cdot {v}_{i} )}^{2}} \\ = \frac{{\sum }_{i = 1}^{{N}_{{A}_{0}}} {α}_{i} ( ω ) \cdot {E}_{{A}_{0}} ( ω , a ) + {\sum }_{j = 1}^{{N}_{{S}_{0}}} {β}_{j} ( ω ) \cdot {E}_{{S}_{0}} ( ω , a )}{{v}_{i}^{2}}\end{matrix} \qquad Eq . ( 16 )$$

wherein:
E_{νo} and E_{νi} are the energies from the output and input signals, respectively;
Eⁱ_{νpAo} is the energy of the ith reflected response of the fundamental antisymmetric mode (A₀);
Eⁱ_{νpSo} is the energy of the ith reflected response of the fundamental symmetric mode (S₀);
N_{Ao} and N_{So} are the total number of the reflected responses within the given measurement duration (note that N_{So} is greater than N_{Ao} because S₀ mode always travels faster than A₀ mode);
αᵢ and βⱼ are ith and jth response coefficients which depend on the reflection, attenuation, and dispersion for antisymmetric and symmetric modes, respectively;
E_{Ao} and E_{So} are the energy packet of A₀ and S₀ modes generated by the transducer at the given input frequency; and
α is the half of the length of the transducer.
   Note that the LWER index is expected to converge to a certain value because of the attenuation of the reflections after traveling along the paths multiple times.

As shown in Equation (16), the amplitudes of Lamb wave modes depend on the size of the piezoelectric transducer and the driving frequency, assuming that all the material properties of the transducer are constant. Therefore, the Lamb wave energy plot with respect to the driving frequency moves horizontally as a function of the size of the transducer. On the other hand, temperature variation changes the overall Lamb wave energy level and moves the corresponding Lamb wave energy plot vertically. Therefore, the cracking, which effectively causes a change in the size of the transducer, can be distinguished from temperature variation. Note that the driving frequency range is chosen such that only the fundamental Lamb wave modes are generated in this example. A main advantage of this LWER-based scheme is to differentiate cracking from temperature variation. The effects of the transducer size and temperature variation is analyzed in detail in the Numerical Simulation section, immediately below.

### Numerical Simulation

The theoretical basis of the TRP- and LWER-based self-diagnosing schemes described above was first verified through two-dimensional numerical simulations. These simulations were performed using PZFlex® software, available from Weidlinger Associates, Inc., Mountain View, Calif. (www.pzflex.com), because it supports the self-sensing function of the piezoelectric element.

### Simulation Set-Up

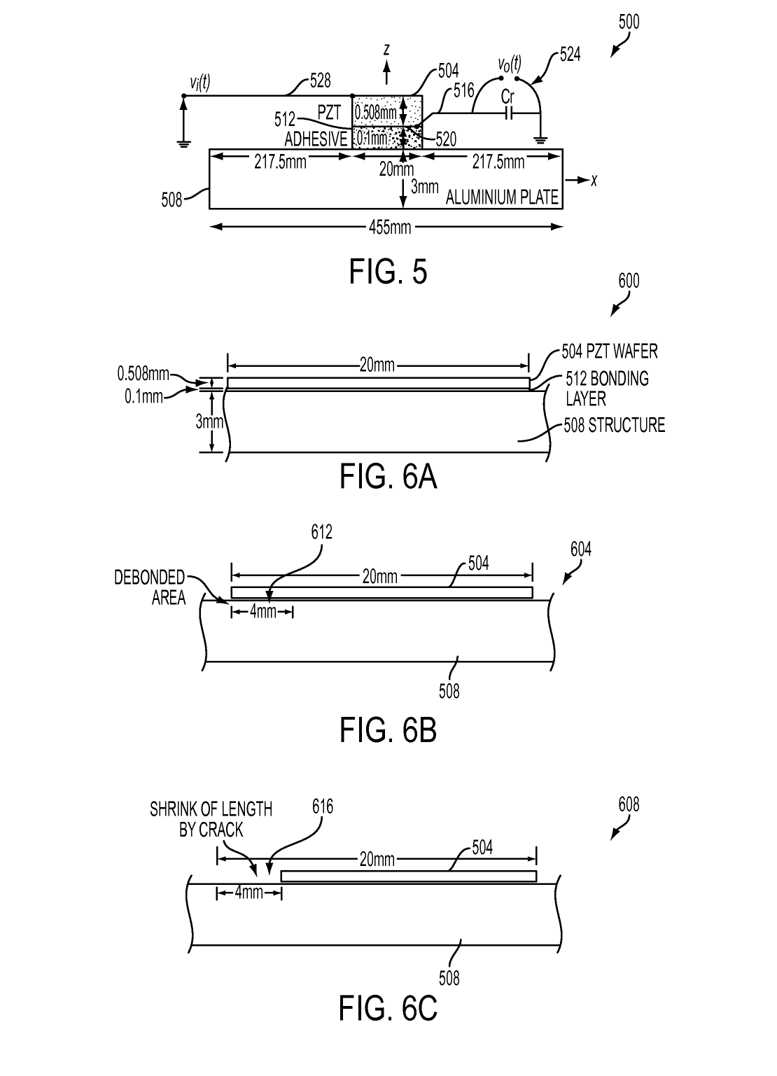

FIG. 5 shows the model 500 used in the simulations. Model 500 included a single PZT layer 504 attached to a plate 508 with an adhesive layer 512. In the simulations, the length of plate 508 was 455 mm, and its thickness was 3 mm. A bottom electrode 516 was connected between the bottom 520 of PZT layer 504 and a self-sensing circuit 524 of the present invention. A narrowband toneburst input signal (Vᵢ(t)) was applied to a top electrode 528 connected to PZT layer 504. The corresponding output signal (Vₒ(t)) was measured through self-sensing circuit 524. Since the finite element method (FEM) simulation was two dimensional, the lengths of PZT layer 504 and adhesive layer 512 were shortened for simulating the cracked and debonded PZT wafers, respectively.

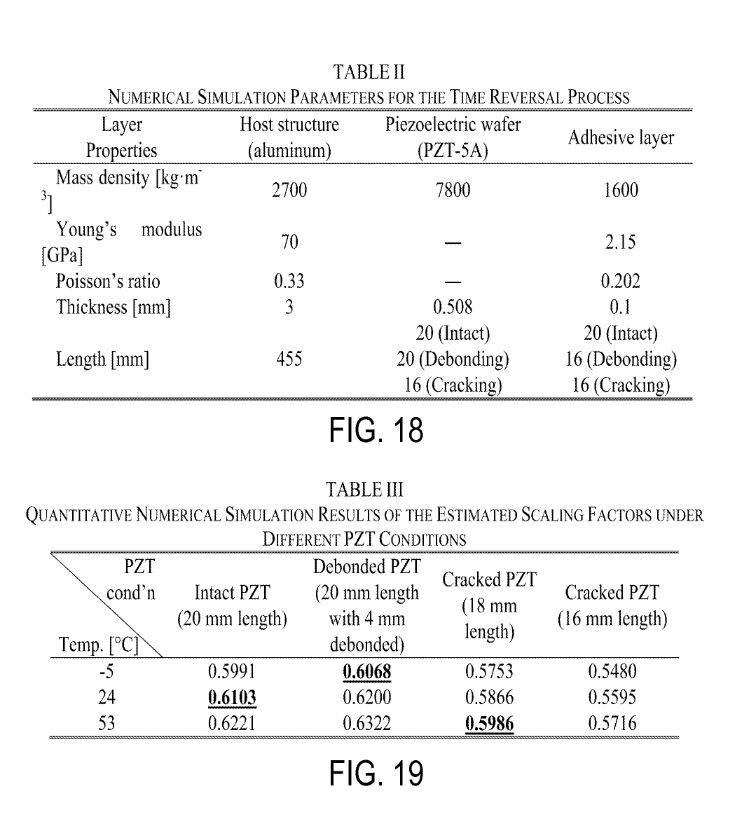

Table II of FIG. 18 shows the material properties and dimensions of PZT layer 504, plate 508, and adhesive layer 512 used for the numerical simulations. The piezoceramic properties of PZT layer 504 used in this study (PZT-5A) were obtained from the manufacturer's specification. The maximum mesh size was 1 mm by 1 mm. The sampling rate was 5 MHz. Note that the changes of material properties of the PZT wafer, the adhesive, and the structure for different temperature conditions were considered together.

### Scaling Factor Index

This subsection presents details of two-dimensional numerical simulations that were performed for measuring the scaling factor to validate the theoretical analysis based on the admittance model discussed above. Three different lengths of PZT layer 504 (16/18/20 mm) and the debonded PZT condition were examined under three different temperature conditions (−5/24/53° C.). FIGS. 6A-C illustrate, respectively, the models 600, 604, 608 used for PZT 504 (FIG. 5) being intact, the PZT wafer being debonded over a length of 4 mm at region 612, and the PZT layer being cracked at a distance of 4 mm from the left end 512 of the PZT layer, which effectively shortens the PZT layer by an amount 616 beyond the crack.

Table III of FIG. 19 shows the measured scaling factors with four different conditions of PZT layer 504 under three different temperature conditions, with a ±10 V peak-to-peak voltage and a driving frequency of 10 kHz. Table III clearly shows the need for an additional self-diagnosis feature to differentiate the defects of PZT layer 504 from temperature variation. Otherwise, the PZT capacitance increase due to temperature increase can be misinterpreted as being caused by debonding of PZT layer 504. Similarly, the decrease in the capacitance of PZT layer 504 due to temperature drop can be misunderstood as being caused by cracking of the PZT layer, or, conversely, the decrease in capacitance due to cracking of the PZT layer can be masked by a temperature increase. Also, the increase in capacitance of PZT layer 504 due to the PZT debonding defect can be masked due to a temperature drop.

### TR/SYM Indices

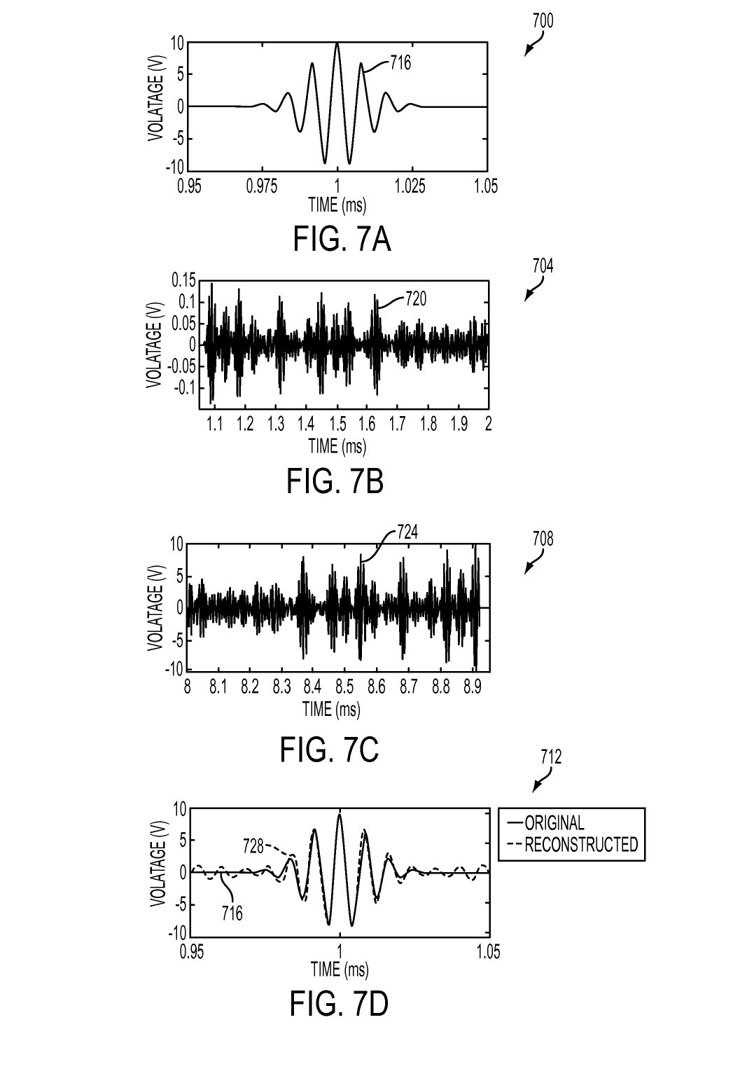

This subsection presents details of two-dimensional numerical simulations that were performed to examine the robustness of the TRP-based scheme, theoretically derived above, to temperature variation and to the intact and cracked conditions. FIGS. 7A-D are, respectively, graphs 700, 704, 708, 712 showing signals related to the TRP from the intact PZT layer 504 as shown in FIG. 5. Graph 700 of FIG. 7A shows the original input waveform 716 (a 120 kHz toneburst signal) in the time domain that is input into PZT layer 504 (FIG. 5). Waveform 716 corresponds to waveform 312 of FIG. 3. Graph 704 of FIG. 7B illustrates the measured mechanical response signal 720 from PZT layer 504. Measured mechanical response signal 720 corresponds to waveform 318 of FIG. 3. Similarly, graph 708 of FIG. 7C shows the reversed response signal 724, which is a reversed and scaled version of the measured mechanical response signal 720 in the time domain. Reversed response signal 724 corresponds to waveform 322 of FIG. 3. Graph 712 of FIG. 7D shows the reconstructed signal 728 that corresponds to waveform 332 of FIG. 3. As expected in the theoretical analysis, graph 712 of FIG. 7D shows that the shape of “main mode” of reconstructed signal 728 is close to the shape of original input waveform 716. Note that reconstructed signal 728 was reversed and scaled to original input waveform 716 in the time domain for the better comparison with the original input waveform.

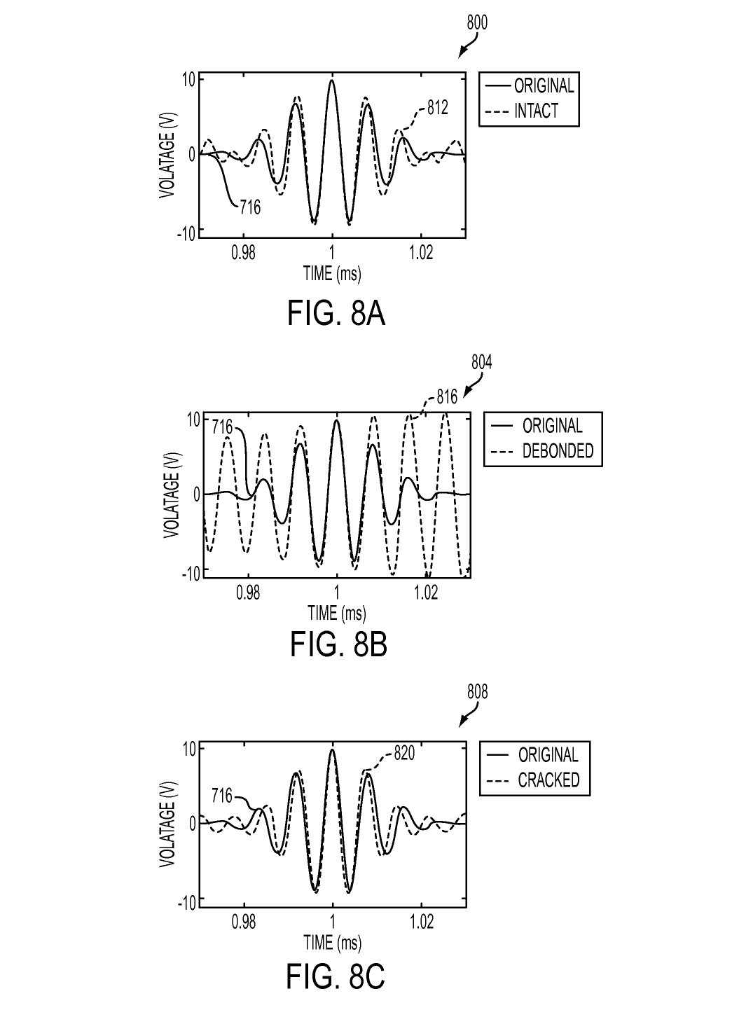

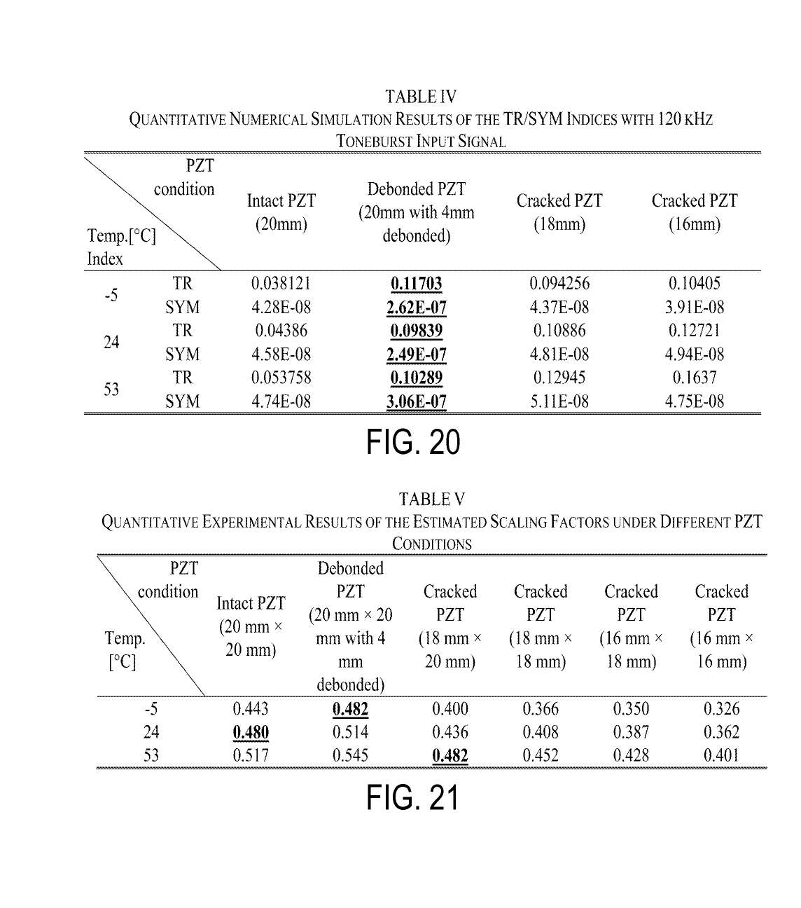

The same TRP simulations for the three different conditions of PZT layer 504 represented by models 700, 704, 708 of FIGS. 7A-C were then performed. As shown in graphs 800, 804, 808 of FIGS. 8A-C, respectively, the reconstructed signal 812, 816, 820 for each case was compared with the original input waveform 716 (from FIG. 7A). For the intact and cracked conditions of PZT layer 504, reconstructed signals 812, 820 (FIGS. 8A and 8C, respectively) were almost the same as the original input waveform 716. However, reconstructed signal 816 for the debonded condition of PZT layer 504 strayed from original input waveform 716. To show the quantitative comparison, the TR and SYM indices were calculated as shown in Table IV of FIG. 20. The SYM index of the debonded condition of PZT layer 504 is about five times larger than those of the intact and cracked conditions of the PZT layer. On the other hand, the TR index of the debonded condition of PZT layer 504 is similar to the TR indices of the cracked conditions of the PZT layer. A possible reason for this is that the measured response in the debonded condition in the numerical simulations is a linear combination of the structural response and free vibration, and the effect of the free vibration in the numerical simulations seems relatively weaker than that in real situations. In addition, the numerical simulations do not reflect uncertain factors, such as nonlinearity caused by the debonded part of the transducer in real experiments. However, from these numerical simulations, it is shown that the debonded condition affects the convergence of the reversed response signal and consequently the shape of the reconstructed signal in the TRP.

### LWER Index

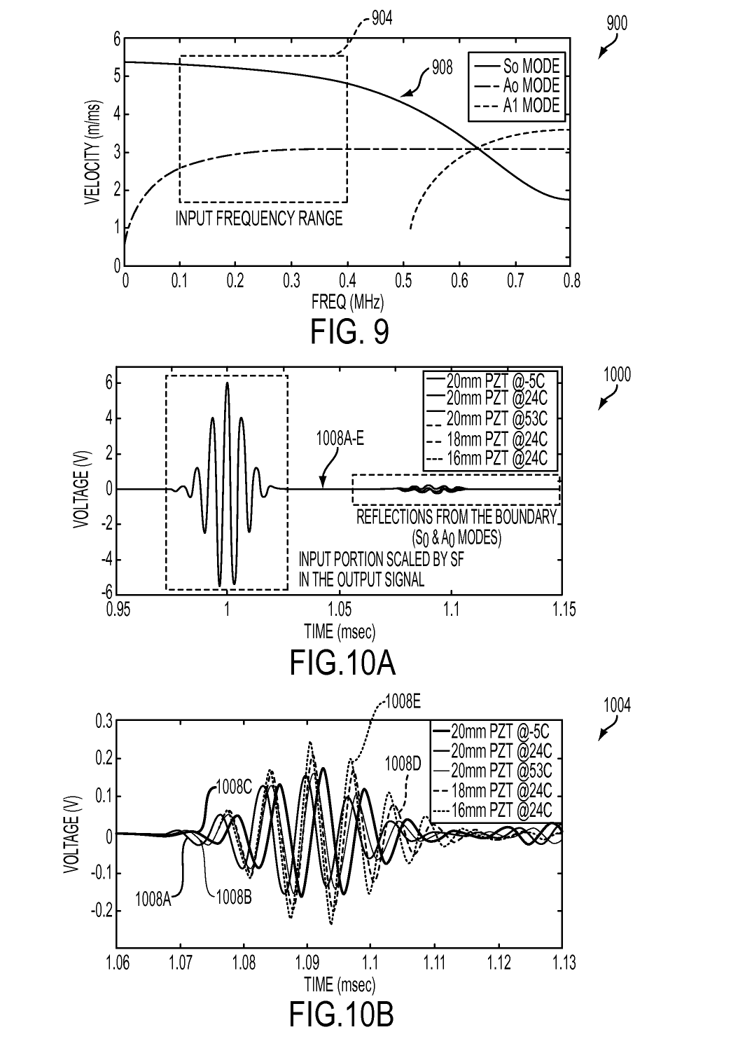

This subsection presents details of two dimensional numerical simulations that were performed to determine the effects of temperature variations and the corresponding material property changes on the LWER index and to examine the robustness of the LWER-based self-diagnosis scheme to environmental variation. To detect a cracking problem, a driving frequency range from 100 kHz to 400 kHz was chosen to measure variation in the LWER index. As illustrated by graph 900 of FIG. 9, this driving frequency range, represented by window 904, was determined by considering the reliability of the electric components and the dispersion curve 908 of 3 mm-thick aluminum plate 508 (FIG. 5) from a commercial software program available from Vallen Systeme GmbH, Munich, Germany, by generating only fundamental Lamb wave modes.

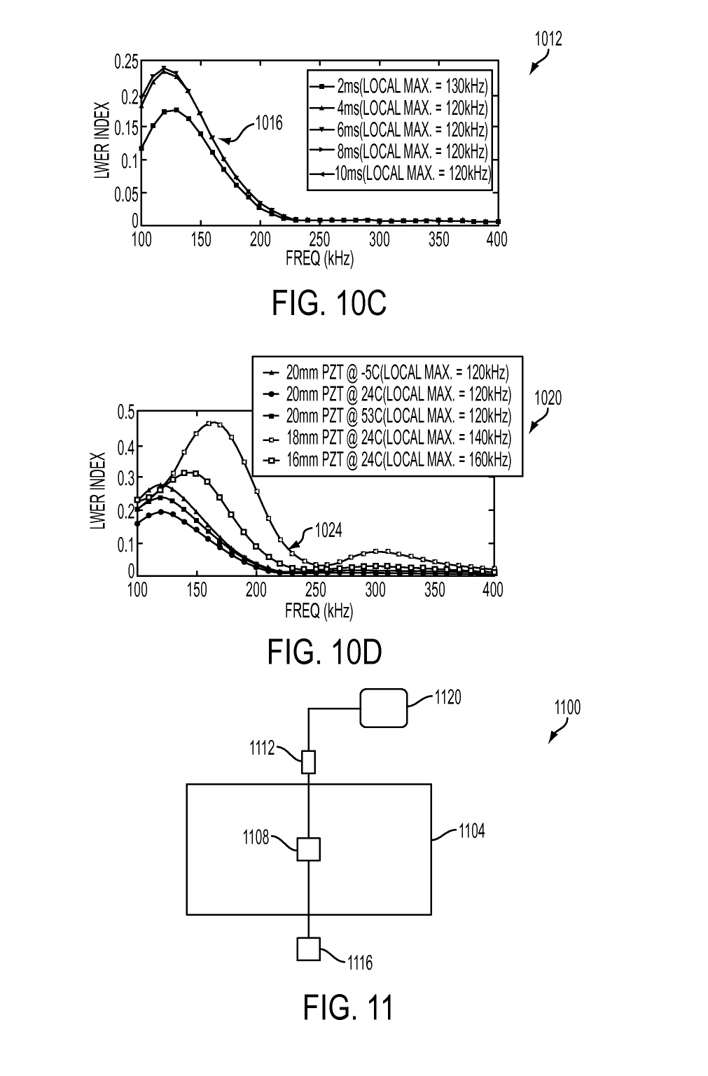

As an example, FIGS. 10A-B are graphs 1000, 1004 showing the measured output response signals 1008A-E at 150 kHz with different lengths of PZT layer 504 (FIG. 5) under various temperature conditions. FIG. 10B is a zoomed-in view of response signals 1008A-E corresponding to the reflection from a boundary with PZT layer 504 and containing the S₀ and A₀ modes. As expected in the theoretical analysis, above, the scaling factor (the capacitance of PZT layer 504) changed according to the lengths of the PZT layer and the temperature conditions, as shown in graph 1000 of FIG. 10A. In addition, graph 1004 of FIG. 10B shows the amplitude and phase change of the first S₀ mode reflection in output response signals 1008A-E. Graph 1004 clearly shows that the direct comparison between a current response and previously-obtained baseline data can result in the false alarm of defects or structural damage of PZT layer 504 because of operational or environmental variations.

FIG. 10C is a graph 1012 of LWER index versus time for an LWER-index plot 1016 that indicates that the LWER index converges after a certain amount of time measurement, as is expected from the theoretical analysis. In other words, LWER-index plot 1016 has the same local maximum frequency after a certain measurement time duration. FIG. 10D is a graph 1020 of LWER index versus frequency for an LWER-index plot 1024 that shows that the LWER index moved in the vertical direction in the given frequency range with respect to the ambient temperature. On the other hand, the LWER index moved in the horizontal direction with respect to the length of PZT layer 504 (FIG. 5). This implies that the LWER index differentiates a cracking defect in PZT layer 504 from temperature variation in the PZT layer. This numerical analysis was examined through experimental tests with various sizes of PZT layer 504 in the following Experimental Validation section.

### Experimental Validation

### Experimental Setup

FIG. 11 illustrates the experimental setup 1100 used to verify the theoretical underpinnings of the self-diagnosis schemes and numerical simulations thereof that are described above. Setup 1100 included a 455 mm×254 mm×3 mm aluminum plate 1104, the size of which was determined by the available space in the temperature chamber (not shown). A single PZT wafer 1108 was attached at the middle of plate 1104 with Permabond 820 cyanoacrylate adhesive (not shown) from Permabond LLC, Pottstown, Pa. (www.permabond.com). Based on the manufacturer's specification, the operating temperature of this adhesive is from −60° C. to 200° C. Setup 1100 also included a self-sensing circuit 1112, an arbitrary waveform generator (AWG) 1116, and a data-acquisition system 1120. Self-sensing circuit 1112 was built on a breadboard using a commercial capacitor (not shown). AWG 1116 had a 16-bit resolution and a 100 Ms/s sampling rate. The input signals from AWG 1116 and the output signals from self-sensing circuit 1112 were measured using a signal digitizer (DIG) (not shown) that was part of data-acquisition system 1120 and supported 14-bit resolution and a 100 Ms/s sampling rate. The operation of AWG 1116 and the DIG was controlled by the commercial software LabVIEW from National Instruments Corporation, Austin, Tex. A commercial refrigerator (not shown) and an isotemperature programmable oven (not shown) from Thermo Fisher Scientific, Waltham, Mass., were used to simulate various temperature conditions.

Without using any additional low-pass filter or power amplifier, the same excitation signal was applied 10 times, and the corresponding signals were averaged in the time domain to improve the signal-to-noise ratio. A time interval of about 5 seconds was taken between two adjacent input excitations to minimize vibration interference among subsequent excitations. The same values of parameters in the numerical simulation were utilized for the rest of the experimental parameters.

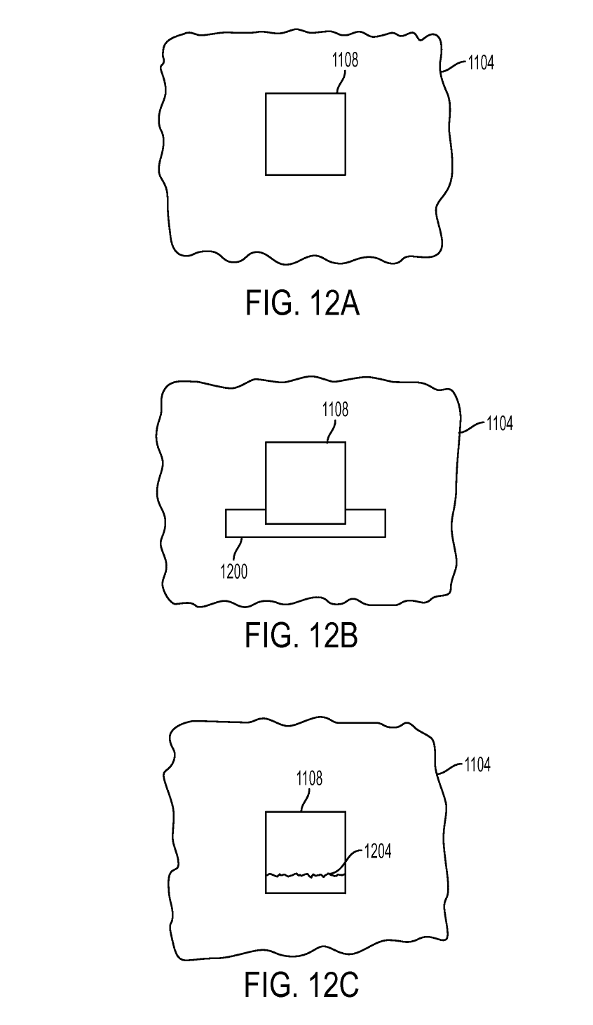

FIGS. 12A-C illustrate the three different conditions of PZT wafer 1108 used in the experiments. In FIG. 12A, PZT wafer 1108 is in an intact condition (20 mm×20 mm×0.508 mm) and fully bonded to plate 1104. In FIG. 12B, a commercial fluoropolymer tape 1200 was partially inserted between PZT wafer 1108 and plate 1104 to prevent bonding of the PZT wafer to the plate at the location of the tape in order to simulate a debonding condition. After the adhesive cured for 24 hours, tape 1200 was removed before performing the experiments. FIG. 12C shows PZT wafer 1108 with a full-length crack 1204 formed using a razor blade (not shown). Note that all the experiments in this study were performed with a single instantiation of PZT wafer 1108 by only changing the conditions from the initial debonded condition to intact and cracked conditions in succession to minimize the unit-to-unit variation that typically occurs in PZT wafers. More particularly, the experiments with the debonded condition were performed first, and then the adhesive was filled into the debonded region between PZT wafer 1108 and plate 1104 to change the PZT condition to an intact, fully-bonded, condition. After completing the experiments with the intact condition, the cracked conditions were prepared consecutively for the “18 mm×20 mm,” “18 mm×18 mm,” “16 mm×18 mm,” and “16 mm×16 mm” sizes. For each condition, three different temperature tests were performed in temperature chambers. To examine the reliability of the self-diagnosis schemes, the same experiment was repeated three times under each temperature condition. In addition, each experiment was performed after 2 hours of heating or cooling, depending on the experiment performed, to stabilize all the material properties at the given temperature condition.

### Scaling Factor Index

This subsection describes the experiments performed to verify the theoretical analysis and the FEM simulation results for identifying a defect in PZT wafer 1108. Table V of FIG. 21 shows the measured scaling factors with six different conditions under three different temperature conditions at a 10 kHz input frequency. Similar to the numerical simulation result, the experimental result shows the necessity of an additional self-diagnosis scheme to differentiate the defects from temperature variation. Otherwise, an increase in capacitance of PZT wafer 1108 due to temperature increase can be misinterpreted as debonding of the PZT wafer from plate 1104. Similarly, a decrease in capacitance of PZT wafer 1108 due to a temperature drop can be misunderstood as by cracking of the PZT wafer.

### TR/SYM Indices

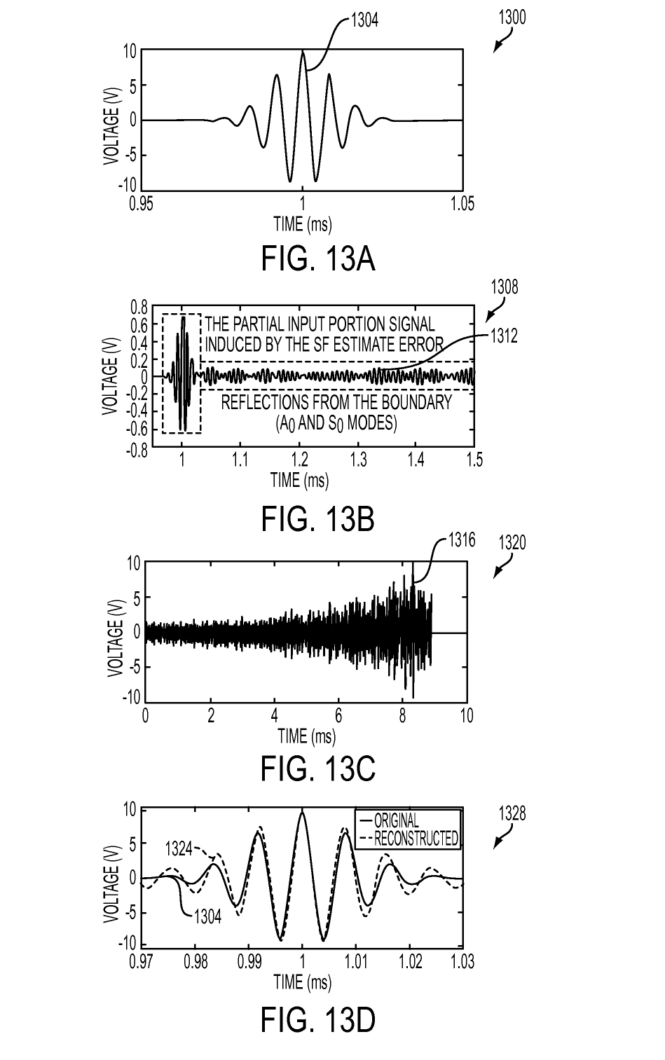

This subsection describes the experiments performed to verify the theoretical analysis and the numerical simulation results for identifying a debonding defect. As shown in graph 1300 of FIG. 13A, the 120 kHz symmetric narrowband toneburst signal applied to the numerical simulations was also used as the input signal 1304 provided by AWG 1116 (FIG. 11) to PZT wafer 1108 for the TRP experiments to measure the TR and SYM indices. Graph 1308 of FIG. 13B shows the mechanical response signal 1312 from PZT wafer 1108 that was measured using data-acquisition system 1120. Mechanical response signal 1312 included a part of input signal 1304 from the scaling factor estimated error at 1 ms and the reflections from the boundary after 1.05 ms. Only the reflections from the boundary were reversed and scaled in the time domain before being applied to PZT wafer 1108 as a reversed response signal 1316, as seen in graph 1320 of FIG. 13C. The second extracted mechanical response, i.e., the reconstructed signal 1324 in graph 1328 of FIG. 13D, was measured and then was time-reversed and scaled in the time domain for the better shape comparison with the original input signal 1304 as shown in FIG. 13D.

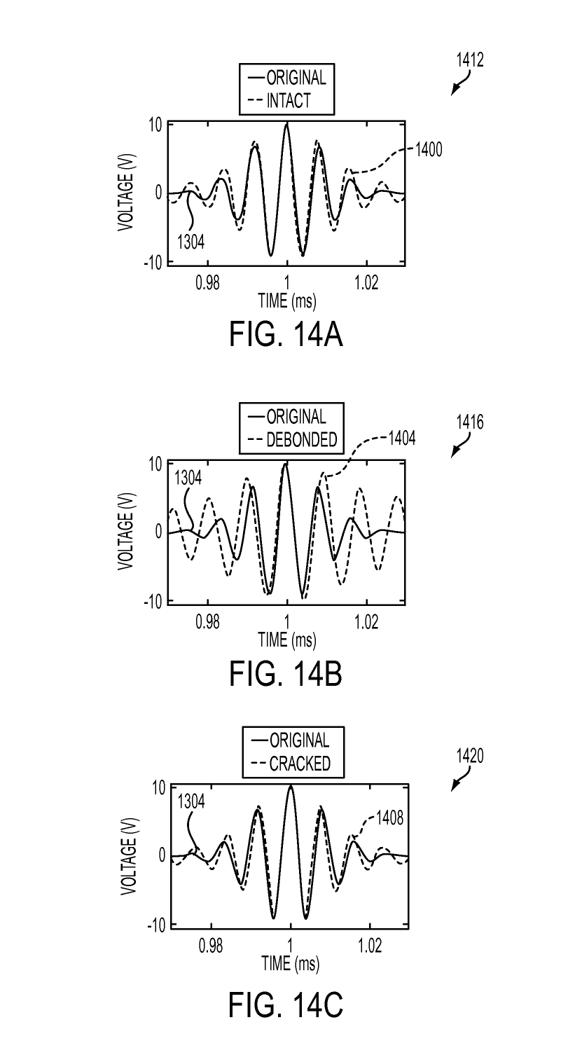

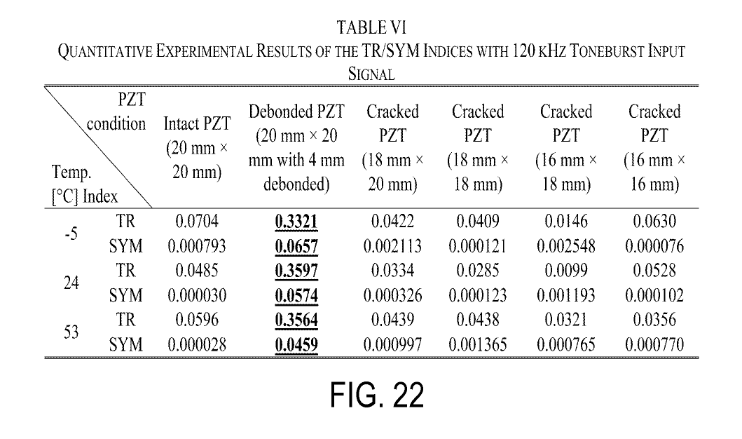

The same TRP experiments were repeated for three different wafer conditions (totally, 6 cases were performed as shown in Table VI of FIG. 22) to obtain the reconstructed signals 1400, 1404, 1408 shown in graphs 1412, 1416, 1420 of FIGS. 14A-C, respectively. Then, the reconstructed signals were compared with the original input signal 1304 shown in FIGS. 14A-C. For the intact and the cracked conditions (FIGS. 14A and 14C, respectively), the time reversibility and symmetry of reconstructed signals 1400, 1408 were not affected as shown in FIGS. 14A and 14C and in Table VI of FIG. 22. On the other hand, for the debonding condition (FIG. 14B), the time reversibility and symmetry were no longer valid, as shown in FIG. 14B. The corresponding TR and SYM indices increase more than 8 and 1000 times compared with those of the intact condition, respectively. These results are well matched with the theoretical analysis. Note that the temperature variation changes the arrival time of Lamb waves, but does not affect the time reversibility and symmetry. This characteristic, which is robust to temperature variation, makes the schemes of the present invention more attractive than other sensor self-diagnosis methods such as the E/M impedance method. In addition, the disclosed indices do not rely on baseline data, which would have to be obtained previously. Using only currently-measured data, the question whether the transducer under the inspection has a debonding problem can be monitored and identified easily.

### LWER Index

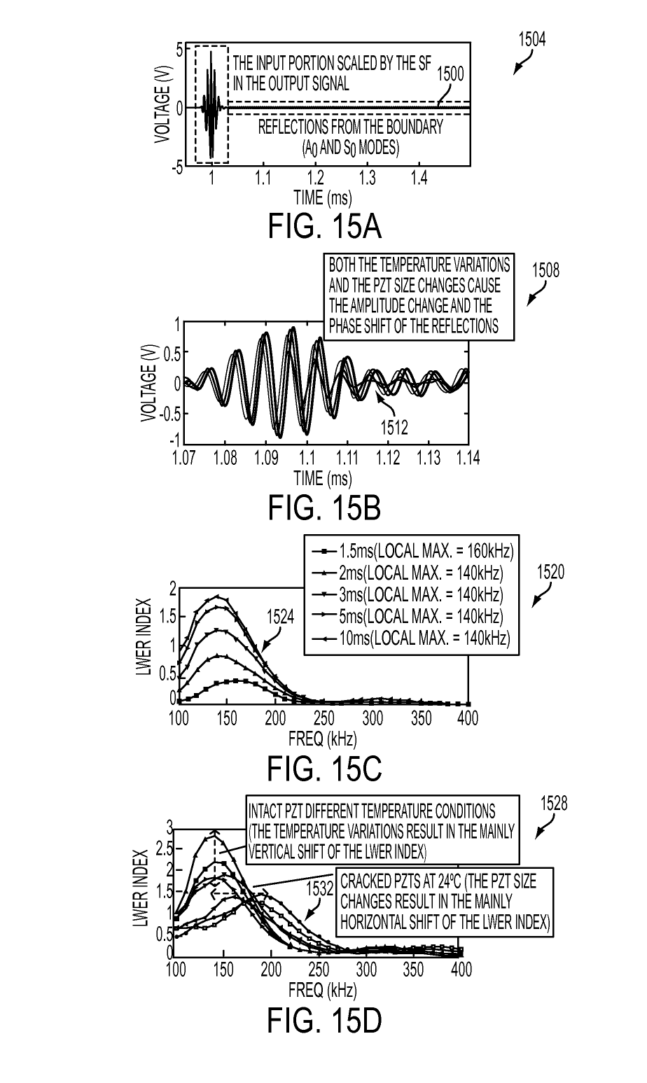

This subsection describes the experiments performed to verify the theoretical analysis and the numerical simulation results for identifying a cracking defect. For comparison to the corresponding numerical simulation result, these experiments included measuring the output signals when a 150 kHz toneburst input signal, i.e., signal 1500 in graph 1504 of FIG. 15A, was applied to PZT wafer 1108 having differing sizes (differing conditions relative to cracking) under varying temperature. Similar to the numerical simulation result, the amplitude and phase of S₀-mode reflections change according to the size of PZT wafer 1108 or temperature condition. Since the background noise was also measured and sometimes an undesired bias existed, the measured responses were refined by a continuous wavelet transform (CWT) filtering technique and then were compared among differing cases. This is illustrated by graph 1508 of FIG. 15B, which shows a plot 1512 of the CWT-filtered output voltages (first S₀ reflection) for the differing cases.

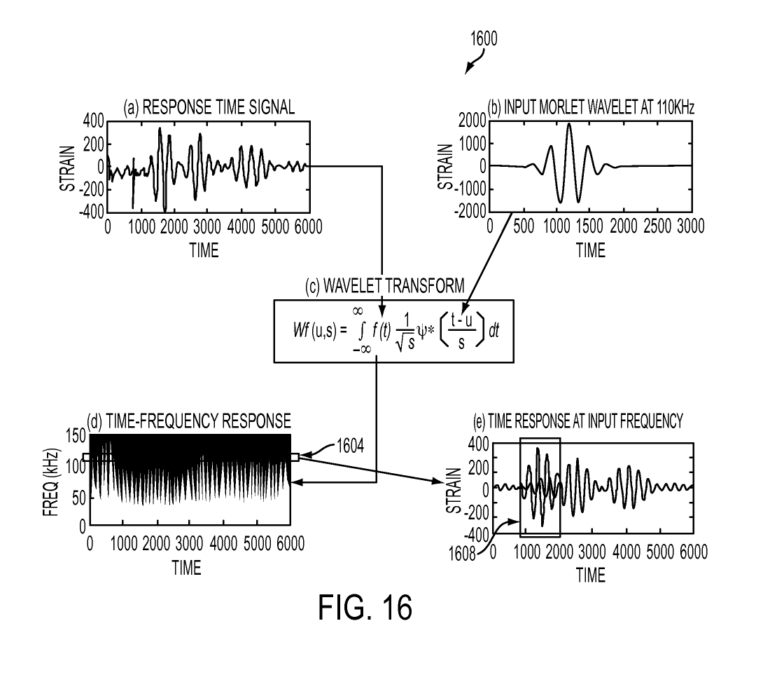

A CWT-filtering technique, such as CWT-filtering technique 1600 of FIG. 16, is applied in order to remove undesired noise signals from the experimental data and extract an input frequency component in the measured response. In real applications, since Lamb wave mode responses reflected from a boundary are relatively small and sensitive to background noise, CWT filtering technique 1600 is applied to extract the signal only related to the input frequency. The CWT of a signal f(t) by using the mother wavelet f(t) is defined as:

$$Wf ( u , s ) = {\int }_{- ∞}^{∞} f ( t ) \frac{1}{\sqrt{s}} {ψ}_{u , s}^{*} ( t ) d t \\ wherein \text{:} \\ {ψ}_{u , s}^{*} ( t ) = \frac{1}{\sqrt{s}} ψ ( \frac{t - u}{s} ) ; and \qquad Eq . ( 17 )$$

u and s are the translation and dilation (scale) of the mother wavelet.
   The relation between the scale and the filtering frequency is described as:

$$s = \frac{center frequency of the wavelet}{( filtering frequency ) \times ( sampling interval )} \qquad Eq . ( 18 )$$

Using Equation (18), an input frequency component in the measured response, such as the component shown in the frequency domain at 1604 and in the time domain at 1608, can be extracted from the CWT filtering with the corresponding single scale value.

Similar to the numerical simulation result for the LWER index, the convergence of the LWER index with respect to measurement time durations was also verified experimentally as shown by the LWER index versus frequency graph 1520 of FIG. 15C, which contains an LWER-index plot 1524 that, like LWER-index plot 1016 of FIG. 10C indicates that the LWER index converges after a certain amount of time measurement, as is expected from the theoretical analysis. FIG. 15D is a graph 1528 of LWER index versus frequency for an LWER-index plot 1532 that shows that the LWER index moved in the vertical direction in the given frequency range with respect to the ambient temperature. On the other hand, the LWER index moved in the horizontal direction with respect to the length of PZT wafer 1108 (FIG. 11). Like LWER-index plot 1024 of FIG. 10D, this implies that the LWER index differentiates a cracking defect in PZT wafer 1108 from temperature variation in the PZT wafer. This result validates the theoretical analysis and the numerical simulation of the LWER index that an LWER-based self-diagnosis scheme of the present invention can differentiate transducer cracking from temperature variation. The size decrease in PZT wafer 1108 caused by cracking, can be successfully identified by observing the horizontal shift of the LWER index.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A method, comprising:
monitoring a piezoelectric transducer for a change in capacitance of the piezoelectric transducer; and
implementing, as a function of said monitoring, a baseline-free process to determine if a defect condition is present or if the change in capacitance is due to a change in temperature of the piezoelectric transducer.

2. A method according to claim 1, wherein said monitoring the piezoelectric transducer includes measuring a scaling factor between an input voltage input into the piezoelectric transducer and a corresponding output voltage output from the piezoelectric transducer.

3. A method according to claim 2, wherein said measuring the scaling factor includes measuring the scaling factor as a ratio of the capacitance of the piezoelectric transducer to the summation of the piezoelectric transducer capacitance and the capacitance of a capacitor in electrical series with the piezoelectric transducer.

4. A method according to claim 1, further comprising determining whether the change in capacitance is an increase in the capacitance, wherein said implementing the baseline-free process includes implementing a baseline-free process to determine if the piezoelectric transducer is at least partially debonded from a host structure.

5. A method according to claim 4, wherein said implementing the baseline-free process includes:
inputting an input signal into the piezoelectric transducer;
generating a response signal representing the response of the piezoelectric transducer to the input signal;
time-reversing the response signal to obtain a time-reversed response signal;
inputting the time-reversed response signal into the piezoelectric transducer;
obtaining a reconstructed signal representing the response of the piezoelectric transducer to time-reversed response signal; and
comparing the reconstructed signal to the input signal.

6. A method according to claim 5, wherein said comparing the reconstructed signal to the input signal includes calculating a time-reversal index as a function of the reconstructed signal and the input signal.

7. A method according to claim 6, wherein said calculating the time-reversal index includes calculating the time-reversal index (TR) as follows:
$$TR = 1 - \sqrt{\frac{{\{ {\sum }_{k = {M}_{L}}^{{M}_{R}} I [ k ] \cdot V [ k ] \}}^{2}}{\{ {\sum }_{k = {M}_{L}}^{{M}_{R}} {( I [ k ] )}^{2} \cdot {\sum }_{k = {M}_{L}}^{{M}_{R}} {( V [ k ] )}^{2} \}}}$$
wherein:
I[k] and V[k] denote the discrete version of the input signal (Vᵢ(t)) and the reconstructed signal (V_{rc}(t)), respectively; and
M_{L} and M_{R} represent the starting and ending data points, respectively, of a time interval from a first peak of a main mode of the reconstructed signal and a seventh peak of the main mode.

8. A method according to claim 6, wherein said comparing the reconstructed signal to the input signal further includes calculating a symmetry index as a function of the reconstructed signal and the input signal.

9. A method according to claim 8, wherein said implementing the baseline-free process includes determining whether the time-reversal and symmetry indices have changed over time.

10. A method according to claim 9, further comprising, when the time-reversal and symmetry indices have changed over time, determining a debonding defect condition is present in the piezoelectric transducer.

11. A method according to claim 10, further comprising, in response to determining the debonding defect condition is present, taking an action based on the debonding defect condition being present.

12. A method according to claim 5, wherein said comparing the reconstructed signal to the input signal includes calculating a symmetry index as a function of the reconstructed signal and the input signal.

13. A method according to claim 6, wherein said calculating the time-reversal index includes calculating the symmetry index (SYM) as follows:
$$SYM = 1 - \sqrt{\frac{{\{ {\sum }_{k = {M}_{L}}^{{M}_{0}} L [ k ] \cdot R [ 2 {M}_{0} - k ] \}}^{2}}{\{ {\sum }_{k = {M}_{L}}^{{M}_{0}} {( L [ k ] )}^{2} \cdot {\sum }_{k = {M}_{0}}^{{M}_{R}} {( R [ k ] )}^{2} \}}}$$
wherein:
L[k] and R[k] denote the discrete version of left-hand and right-hand sides of a main mode of the reconstructed signal (V_{rc}(t)) with respect to a center of the main mode;
M₀ is the center data point of the main mode; and
M_{L} and M_{R} represent the starting and ending data points, respectively, of a time interval from a first peak of the main mode of the reconstructed signal and a seventh peak of the main mode.

14. A method according to claim 1, further comprising determining whether the change in the capacitance is a decrease in the capacitance, wherein said implementing the baseline-free process includes implementing a baseline-free process to determine if the piezoelectric transducer contains an internal crack.

15. A method according to claim 14, wherein said implementing the baseline-free process includes:
applying a driving signal to the piezoelectric transducer at a selected frequency;
generating an output signal representing the output of the piezoelectric transducer that corresponds to the driving signal; and
determining a Lamb wave energy ratio index as a function of the driving signal and the output signal.

16. A method according to claim 15, wherein said determining the Lamb wave energy ratio index includes calculating the Lamb wave energy ratio index as follows:
$$\begin{matrix}LWER ( ω , a ) = \frac{{E}_{{v}_{o}} ( ω , a )}{{E}_{{v}_{i}} ( ω , a )} \\ = \frac{{SF}^{2} \cdot ( {\sum }_{i = 1}^{{N}_{Ao}} {E}_{{v}_{{p}_{{A}_{0}}}}^{i} ( ω , a ) + {\sum }_{j = 1}^{{N}_{So}} {E}_{{v}_{{p}_{{S}_{0}}}}^{j} ( ω , a ) )}{{( SF \cdot {v}_{i} )}^{2}} \\ = \frac{{\sum }_{i = 1}^{{N}_{{A}_{0}}} {α}_{i} ( ω ) \cdot {E}_{{A}_{0}} ( ω , a ) + {\sum }_{j = 1}^{{N}_{{S}_{0}}} {β}_{j} ( ω ) \cdot {E}_{{S}_{0}} ( ω , a )}{{v}_{i}^{2}}\end{matrix}$$
wherein:
E_{νo} and E_{νi} are the energies from the output and input signals, respectively;
Eⁱ_{νpAo} is the energy of the ith reflected response of a fundamental antisymmetric mode (A₀);
Eⁱ_{νpSo} is the energy of the ith reflected response of a fundamental symmetric mode (S₀);
N_{Ao} and N_{So} are the total number of the reflected responses within the given measurement duration;
αᵢ and βⱼ are ith and jth response coefficients which depend on reflection, attenuation, and dispersion for antisymmetric and symmetric modes, respectively;
E_{Ao} and E_{So} are energy packets of A₀ and S₀ modes generated by the piezoelectric transducer at the given input frequency; and
α is half of a length of the piezoelectric transducer.

17. A method according to claim 15, wherein said implementing the baseline-free response process includes determining whether the Lamb wave energy ratio index has changed over time.

18. A method according to claim 17, further comprising, when the Lamb wave energy ratio index has changed over time, determining a cracking defect condition is present in the piezoelectric transducer.

19. A method according to claim 18, further comprising, in response to determining the cracking defect condition is present, taking an action based on the cracking defect condition being present.

20. A method, comprising:
repeatingly inputting an input signal into a piezoelectric transducer secured to a host structure;
repeatingly generating a response signal representing the response of the piezoelectric transducer to the input signal;
repeatingly time-reversing the response signal to obtain a time-reversed response signal;
repeatingly inputting the time-reversed response signal into the piezoelectric transducer;
repeatingly obtaining a reconstructed signal representing the response of the piezoelectric transducer to time-reversed response signal;
repeatingly calculating time-reversal and symmetry indices as a function of the reconstructed signal and the input signal;
monitoring the time-reversal and symmetry indices over time to determine when a change occurs in the time-reversal and symmetry indices; and
in response to the change occurring, automatedly taking an action.

21. A method according to claim 20, wherein said automatedly taking an action includes issuing a notification that a debonding defect is present between the piezoelectric transducer and the host structure.

22. A method, comprising:
repeatingly applying a driving signal to the piezoelectric transducer at a selected frequency;
repeatingly generating an output signal representing the output of the piezoelectric transducer that corresponds to the driving signal;
repeatingly determining a Lamb wave energy ratio index as a function of the driving signal and the output signal;
monitoring the Lamb wave energy ratio index over time to determine when a change occurs in the Lamb wave energy ratio index; and
in response to the change occurring, automatedly taking an action.

23. A method according to claim 22, wherein said automatedly taking an action includes issuing a notification that a cracking defect is present in the piezoelectric transducer.

24. A machine-readable medium containing machine-executable instructions for implementing a method of self-diagnosing a piezoelectric transducer, said machine-executable instructions comprising:
a first set of machine-executable instructions for monitoring the piezoelectric transducer for a change in capacitance of the piezoelectric transducer; and
a second set of machine-executable instructions for implementing, as a function of the monitoring, a baseline-free process to determine if a defect condition is present or if the change in capacitance is due to a change in temperature of the piezoelectric transducer.

25. A machine-readable medium according to claim 24, wherein said first set of machine-executable instructions includes machine-executable instructions for measuring a scaling factor between an input voltage input into the piezoelectric transducer and a corresponding output voltage output from the piezoelectric transducer.

26. A machine-readable medium according to claim 25, wherein said machine-executable instructions for measuring the scaling factor includes machine-executable instructions for measuring the scaling factor as a function of the capacitance of the piezoelectric transducer and the capacitance of a capacitor in electrical series with the piezoelectric transducer.

27. A machine-readable medium according to claim 24, further comprising machine-executable instructions for determining whether the change in capacitance is an increase in capacitance, wherein said second set of machine-executable instructions includes machine-executable instructions for implementing a baseline-free process to determine if the piezoelectric transducer is at least partially debonded from a host structure.

28. A machine-readable medium according to claim 27, wherein said machine-executable instructions for implementing the baseline-free process includes machine-executable instructions for:
inputting an input signal into the piezoelectric transducer;
generating a response signal representing the response of the piezoelectric transducer to the input signal;
time-reversing the response signal to obtain a time-reversed response signal;
inputting the time-reversed response signal into the piezoelectric transducer;
obtaining a reconstructed signal representing the response of the piezoelectric transducer to time-reversed response signal; and
comparing the reconstructed signal to the input signal.

29. A machine-readable medium according to claim 28, wherein said machine-executable instructions for comparing the reconstructed signal to the input signal includes machine-executable instructions for calculating time-reversal and symmetry indices as a function of the reconstructed signal and the input signal.

30. A machine-readable medium according to claim 29, wherein said machine-executable instructions for implementing the baseline-free process includes machine-executable instructions for determining whether the time-reversal and symmetry indices have changed over time.

31. A machine-readable medium according to claim 30, further comprising machine-executable instructions for determining a debonding defect condition is present in the piezoelectric transducer when the time-reversal and symmetry indices have changed over time.

32. A machine-readable medium according to claim 26, further comprising machine-executable instructions for taking an action based on the debonding defect condition being present.

33. A machine-readable medium according to claim 24, further comprising machine-executable instructions for determining whether the change in capacitance is an increase in capacitance, wherein said machine-executable instructions for implementing the baseline-free process includes machine-executable instructions for implementing a baseline-free process to determine if the piezoelectric transducer is at least partially debonded from a host structure.

34. A machine-readable medium according to claim 33, wherein said machine-executable instructions for implementing the baseline-free process includes machine-executable instructions for:
applying a driving signal to the piezoelectric transducer at a selected frequency;
generating an output signal representing the output of the piezoelectric transducer that corresponds to the driving signal; and
determining a Lamb wave energy ratio index as a function of the driving signal and the output signal.

35. A machine-readable medium according to claim 34, wherein said machine-executable instructions for implementing the baseline-free response process includes machine-executable instructions for determining whether the Lamb wave energy ratio index has changed over time.

36. A machine-readable medium according to claim 35, further comprising machine-executable instructions for determining a cracking defect condition is present in the piezoelectric transducer when the Lamb wave energy ratio index has changed over time.

37. A machine-readable medium according to claim 36, further comprising machine-executable instructions for taking an action based on the debonding defect condition being present.

38. A machine-readable medium containing machine-executable instructions for implementing a method of self-diagnosing a piezoelectric transducer, said machine-executable instructions comprising:
machine-executable instructions for repeatingly inputting an input signal into a piezoelectric transducer secured to a host structure;
machine-executable instructions for repeatingly generating a response signal representing the response of the piezoelectric transducer to the input signal;
machine-executable instructions for repeatingly time-reversing the response signal to obtain a time-reversed response signal;
machine-executable instructions for repeatingly inputting the time-reversed response signal into the piezoelectric transducer;
machine-executable instructions for repeatingly obtaining a reconstructed signal representing the response of the piezoelectric transducer to time-reversed response signal;
machine-executable instructions for repeatingly calculating time-reversal and symmetry indices as a function of the reconstructed signal and the input signal;
machine-executable instructions for monitoring the time-reversal and symmetry indices over time to determine when a change occurs in the time-reversal and symmetry indices; and
machine-executable instructions for automatedly taking an action in response to the change occurring.

39. A machine-readable medium according to claim 38, wherein said machine-executable instructions for automatedly taking an action includes machine-executable instructions for issuing a notification that a debonding defect is present between the piezoelectric transducer and the host structure.

40. A machine-readable medium containing machine-executable instructions for implementing a method of self-diagnosing a piezoelectric transducer, said machine-executable instructions comprising:
machine-executable instructions for repeatingly applying a driving signal to the piezoelectric transducer at a selected frequency;
machine-executable instructions for repeatingly generating an output signal representing the output of the piezoelectric transducer that corresponds to the driving signal;
machine-executable instructions for repeatingly determining a Lamb wave energy ratio index as a function of the driving signal and the output signal;
machine-executable instructions for monitoring the Lamb wave energy ratio index over time to determine when a change occurs in the Lamb wave energy ratio index; and
machine-executable instructions for automatedly taking an action in response to the change occurring.

41. A machine-readable medium according to claim 340, wherein said machine-executable instructions for automatedly taking an action includes machine-executable instructions for issuing a notification that a cracking defect is present in the piezoelectric transducer.

42. A transducer system, comprising:
a piezoelectric transducer having a capacitance; and
a self-diagnosis system configured for:
monitoring said piezoelectric transducer for a change in the capacitance of said piezoelectric transducer; and
implementing, as a function of the monitoring, a baseline-free process to determine if a defect condition is present or if the change in capacitance is due to a change in temperature of the piezoelectric transducer.

43. A transducer system according to claim 42, wherein said self-diagnosis system includes a self-sensing circuit electrically connected to said piezoelectric transducer, said self-sensing circuit being in the form of a voltage divider having a measurement leg and a capacitor in electrical parallel with the measurement leg.

44. A transducer system according to claim 42, wherein said self-diagnosis system includes a waveform generator electrically connected to said piezoelectric transducer and configured to input a toneburst signal into said piezoelectric transducer.

45. A transducer system according to claim 44, wherein said self-diagnosis system includes a self-sensing circuit for sensing the response of the piezoelectric transducer to the toneburst signal.

46. A transducer system according to claim 45, wherein said sensing circuit includes a measuring leg and a capacitor in electrical parallel with said measuring leg, wherein said capacitor has a capacitance.

47. A transducer system according to claim 45, wherein said self-diagnosis system is configured to measure, using said self-sensing circuit, a scaling factor that is a function of the capacitance of said piezoelectric transducer and the capacitance of said capacitor.

48. A transducer system according to claim 42, wherein said self-diagnosis system is configured to determine, when said piezoelectric transducer is attached to a host structure, if said piezoelectric transducer is at least partially debonded from the host structure.

49. A transducer system according to claim 48, wherein said self-diagnosis system is configured to:
input an input signal into said piezoelectric transducer;
generate a response signal representing the response of said piezoelectric transducer to the input signal;
time-reverse the response signal to obtain a time-reversed response signal;
input the time-reversed response signal into said piezoelectric transducer;
obtain a reconstructed signal representing the response of said piezoelectric transducer to time-reversed response signal; and
compare the reconstructed signal to the input signal.

50. A transducer system according to claim 49, wherein said self-diagnosing system is configured to calculate time-reversal and symmetry indices as a function of the reconstructed signal and the input signal.

51. A transducer system according to claim 50, wherein said self-diagnosing system is configured to determine whether the time-reversal and symmetry indices have changed over time.

52. A transducer system according to claim 51, wherein said self-diagnosing system is configured to determine a debonding defect condition is present in said piezoelectric transducer.

53. A transducer system according to claim 52, wherein said self-diagnosing system is configured to take an action based on the debonding defect condition being present.

54. A transducer system according to claim 42, wherein said self-diagnosing system is configured to determine if the piezoelectric transducer contains an internal crack.

55. A transducer system according to claim 53, wherein said self-diagnosis system is configured to:
apply a driving signal to said piezoelectric transducer at a selected frequency;
generate an output signal representing the output of said piezoelectric transducer that corresponds to the driving signal; and
determine a Lamb wave energy ratio index as a function of the driving signal and the output signal.

56. A transducer system according to claim 55, wherein said self-diagnosis system is configured to determine whether the Lamb wave energy ratio index has changed over time.

57. A transducer system according to claim 56, wherein said self-diagnosis system is configured to determine a cracking defect condition is present in the piezoelectric transducer.

58. A transducer system according to claim 57, wherein said self-diagnosis system is configured to take an action based on the cracking defect condition being present.
